(19) United States
(12) Patent Application Publication
(10) Pub. No.: US 2026/0033105 A1
(43) Pub. Date: Jan. 29, 2026

(54) Display Panel and Method of Manufacturing the Same

(71) Applicant: LG Display Co., Ltd., Seoul (KR)

(72) Inventors: Ye Ji Kim, Paju-si (KR); Eun Min Jo, Paju-si (KR)

(21) Appl. No.: 19/239,189

(22) Filed: Jun. 16, 2025

(30) Foreign Application Priority Data
Jul. 23, 2024 (KR) 10-2024-0097150

(51) Int. Cl. H10H 29/855; H01L 25/16; H10H 29/01; H10H 29/03; H10H 29/14; H10H 29/37; H10H 29/49

(52) U.S. Cl. CPC H10H 29/855; H01L 25/167; H10H 29/012; H10H 29/03; H10H 29/0363; H10H 29/142; H10H 29/37; H10H 29/49

(57) ABSTRACT

The present disclosure relates to a display panel and method of manufacturing the same. A display panel comprises a display region and a non-display region disposed outside the display region such that a curved boundary line is between the display region and the non-display region. A plurality of light-emitting elements are in the display region such that the plurality of light-emitting elements are disposed in the display region inside the curved boundary line and the non-display region outside the curved boundary line lacks any light-emitting elements.

### CROSS-REFERENCE TO RELATED APPLICATION

This application claims priority to and the benefit of Republic of Korea Patent Application No. 10-2024-0097150, filed on Jul. 23, 2024, which is hereby incorporated by reference in its entirety.

### 1. TECHNICAL FIELD

The present disclosure relates to a display panel and a method of manufacturing the same, and more specifically, for example, without limitation, to a display device capable of preventing interference between light-emitting element chips by preventing a light-emitting element from being transferred within a trimming line through heterogeneous transfer on an outer part of a display panel, and improving a gap between layers, moisture penetration and corrosion after a reliability test, and the like and a method of manufacturing the same.

### 2. DISCUSSION OF RELATED ART

Display devices include an organic light-emitting display (OLED) device which emits light by itself, a liquid crystal display (LCD) device which requires a separate light source, and the like.

Recently, display devices including light-emitting elements (light-emitting diodes, LEDs) are attracting attention as next generation display devices. The light-emitting elements are formed of an inorganic material rather than an organic material, and thus the display devices including the light-emitting elements may have a faster lighting speed and higher luminous efficacy, and display higher brightness images compared to an LCD device or OLED device.

### SUMMARY

An exemplary embodiment of the present disclosure is directed to providing a display device capable of preventing interference between light-emitting element chips by preventing a light-emitting element from being transferred within a trimming line through heterogeneous transfer on an outer part of a display panel, and improving a gap between layers, moisture penetration and corrosion after a reliability test, and the like and a method of manufacturing the same.

The objects according to exemplary embodiments of the present disclosure are not limited to the above-described objects, and other objects that are not mentioned will be clearly understood by those skilled in the art from the following description.

In one embodiment, a display panel comprises: a display region and a non-display region disposed outside the display region such that a curved boundary line is between the display region and the non-display region; and a plurality of light-emitting elements in the display region, wherein the plurality of light-emitting elements are disposed in the display region inside the curved boundary line and the non-display region outside the curved boundary line lacks any light-emitting elements.

In one embodiment, a display panel comprises: a heterogeneous portion including a display region and a non-display region with a curved boundary line as a boundary between the display region and the non-display region; and a plurality of light-emitting elements in the display region inside of the curved boundary line without any light-emitting elements in the non-display region outside of the curved boundary line.

In one embodiment, a method of manufacturing a display panel, comprises: providing a substrate including a display region and a non-display region where a curved boundary line is between the display region and the non-display region; and disposing a plurality of light-emitting elements in the display region inside the curved boundary line without disposing any light-emitting elements in the non-display region that is outside the curved boundary line.

Specific details according to the various examples of the present disclosure other than solutions to the above-mentioned problems are included in the description and drawings described below.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The following drawings attached to this disclosure illustrate preferred embodiments of the present disclosure and, together with the detailed description of the disclosure to be described below, serve to further understand the technical idea of the present disclosure, and therefore the present disclosure should not be construed as being limited to matters described in such drawings, in which:

FIG. 1 is an exploded perspective view of a display device according to one exemplary embodiment of the present disclosure;

FIG. 2 is a plan view of a display device according to one exemplary embodiment of the present disclosure;

FIG. 3 is an enlarged plan view of a connection structure of a display device according to one exemplary embodiment of the present disclosure;

FIG. 4 is a diagram illustrating a circuit structure according to an exemplary embodiment of the present disclosure.

FIG. 5 is an enlarged view of a display device according to one exemplary embodiment of the present disclosure;

FIG. 6 is a plan view of a display device according to an exemplary embodiment of the present disclosure.

FIG. 7 is a plan view of a display device according to an exemplary embodiment of the present disclosure.

FIG. 8 is a cross-sectional view of a display device according to an exemplary embodiment of the present disclosure.

FIG. 9 is an enlarged cross-sectional view of a display device according to an exemplary embodiment of the present disclosure.

FIG. 10 is an enlarged plan view of a display device according to an exemplary embodiment of the present disclosure;

FIG. 11 is a plan view of the display device according to an exemplary embodiment of the present disclosure;

FIG. 12 is a plan view showing transfer regions of the display device according to an exemplary embodiment of the present disclosure;

FIG. 13 is an enlarged plan view of portion ‘C’ in FIG. 12 according to the exemplary embodiment of the present disclosure;

FIG. 14A is a cross-sectional view showing a picked-up state of a light-emitting element in the display device according to an exemplary embodiment of the present disclosure;

FIG. 14B is a cross-sectional view showing a selective transfer state of the light-emitting element in the display device according to an exemplary embodiment of the present disclosure;

FIG. 15 is a flowchart of a transfer process of the light-emitting element in the display device according to an exemplary embodiment of the present disclosure;

FIGS. 16A to 16C are process diagrams for transferring the light-emitting element of the display device according to an exemplary embodiment of the present disclosure;

FIG. 17A is an enlarged cross-sectional view showing the transfer process of the light-emitting element in a display region in the display device according to an exemplary embodiment of the present disclosure;

FIG. 17B is an enlarged cross-sectional view showing a non-transfer process of the light-emitting element in a non-display region in the display device according to an exemplary embodiment of the present disclosure; and

FIGS. 18 to 21 are views showing devices to which the display device according to exemplary embodiments of the present disclosure is applied.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example. However, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The advantages and features of the present disclosure, and methods of achieving them.

It will become apparent upon reference to the exemplary embodiments described in detail below in conjunction with the accompanying drawings. However, the present disclosure is not limited to the following exemplary embodiments disclosed herein, but may be implemented in various different forms; rather, the present embodiments are provided to make the disclosure of the present disclosure complete and to enable those skilled in the art to fully comprehend the scope of the present disclosure.

The shapes, sizes, proportions, angles, numbers, and the like of elements shown in the

drawings to illustrate embodiments of the present disclosure are merely illustrative and are not intended to be limiting. Identical reference numerals may designate identical components throughout the description. Further, in describing the present disclosure, detailed descriptions of related known technologies may be omitted so as not to obscure the aspects of the present disclosure. Terms such as, “including,” “having,” “comprising” “makeup of,” “formed of,” and the like as used herein are generally intended to allow for the addition of other components, unless the terms are used with the term “only.” References to components of a singular noun include the plural of that noun, unless specifically stated otherwise.

In the interpretation of components, they are construed to include margins of error, even if not explicitly stated. Any implementation described herein as an “example” is not necessarily to be construed as preferred or advantageous over other implementations.

When describing a positional relationship, for example, “on top of,” “above,” “below,” “next to,” “beside,” or “adjacent to” describes the positional relationship of two parts, one or more other parts may be located between the two parts, unless “immediately,” “directly,” or “near to” is used. For example, where an element or layer is disposed “on” another element or layer, a third layer or element may be interposed therebetween.

When describing a temporal relationship, “after,” “following,” “next to,” or “before” describes a temporal antecedent or consequent relationship, which may not be continuous unless “just”, “immediately” or “directly” is used.

The first, the second, “A,” “B,” “(a),” and “(b),” and so on are used to describe various components, but these components are not limited by these terms. These terms are used only to distinguish one component from another. Therefore, the first component referred to below may be a second component within the technical spirit of the present disclosure.

Terms such as first, second, A, B, (a), or (b) may be used to describe elements of the present disclosure. Such terms are intended only to distinguish one component from another and are not intended to define the nature, sequence, order, or number of such components.

When a component is described as being “connected,” “coupled,”, “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contacted” or “overlapped” with another component, it is to be understood that the component may be in direct contacted or overlap with the other component, but that there may also be other components “interposed” between the respective components which may be in direct or indirect contacted or overlap with, unless specifically stated otherwise. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms the first direction, the second direction, the third direction, the X-axis direction, the Y-axis direction, and the Z-axis direction are not to be interpreted solely as a geometric relationship in which the relationship to one another is perpendicular, but may refer to a broader range of orientations in which the configurations of the present disclosure may function.

Each of the features of various embodiments of the present disclosure may be coupled or combined with one another in whole or in part, and may be technologically interlocked and operated in various ways, and each of the embodiments may be carried out independently or in conjunction with one another.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various exemplary embodiments of the present disclosure will be described in detail with reference to the accompanying drawings.

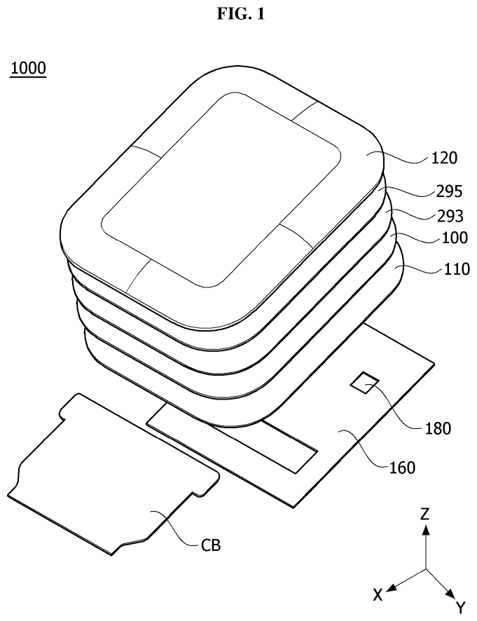

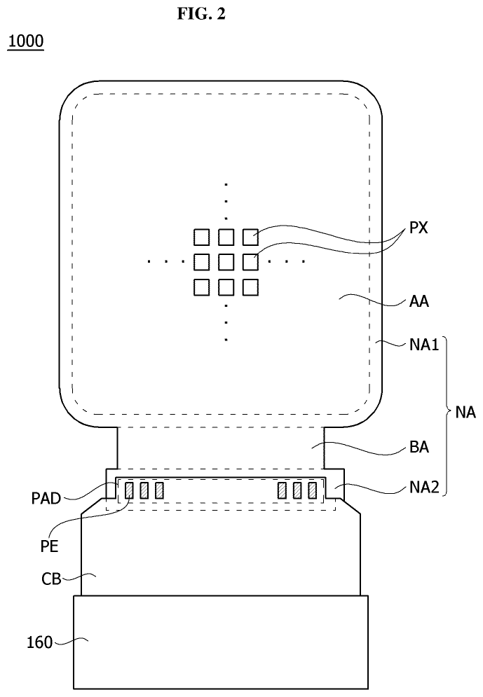

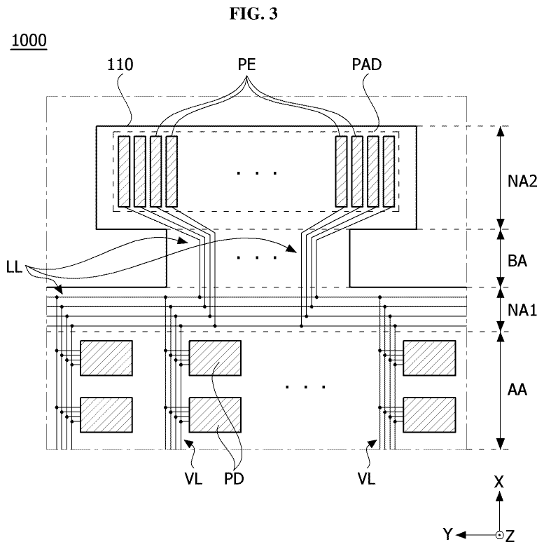

FIG. 1 is an exploded perspective view of a display device according to one embodiment of the present disclosure. FIG. 2 is a plan view of a display device according to one exemplary embodiment of the present disclosure. FIG. 3 is an enlarged plan view of a connection structure of a display device according to one exemplary embodiment of the present disclosure.

Referring to FIGS. 1 to 3, a display device 1000 according to one exemplary embodiment of the present disclosure may include a display panel 100, a polarizing layer 293, an adhesive layer 295, a cover member 120, a support substrate 110, a flexible circuit board CB, and a printed circuit board 160. More or less elements may be included.

For example, the display device 1000 may include a substrate 110. The substrate 110 may be a member that supports other components of the display device 1000. The substrate 110 may be made of an insulating material. For example, the substrate 110 may be made of glass, resin, or the like. Additionally, the substrate 110 may be made of a material having flexibility. For example, the substrate 110 may be made of a flexible plastic material such as polyimide (PI) or the like. However, the embodiments of the present disclosure are not limited thereto.

For example, the substrate 110 may be made of a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is an example and is not necessarily limited thereto.

The display panel 100 may implement information, video, and/or an image provided to a user. For example, the display panel 100 may include a display area AA allowing an image to be displayed and a non-display area NA in which an image is not displayed. The non-display area NA may refer to an area outside of the display area AA. For example, the substrate 110 may include the display area AA and the non-display area NA. The display area AA and non-display area NA are not limited to being described only with respect to the substrate 110 but may be described throughout the entire display device 1000.

The display area AA may be an area in which an image is displayed. The display area AA may include a plurality of pixels PX. Each of the plurality of pixels PX may be composed of a plurality of sub-pixels. A plurality of micro-LEDs may be respectively arranged in the plurality of sub-pixels. The plurality of micro-LEDs may be configured differently depending on the type of display device 1000.

The non-display area NA may be an area in which no image is displayed. Various wires and circuits for driving the plurality of pixels PX of the display area AA may be positioned in the non-display area NA. For example, in the non-display area NA, various wires and driving circuits may be mounted, and a pad portion PAD to which an integrated circuit, a printed circuit, and the like are connected may be provided, but the embodiments of the present disclosure are not limited thereto. At least a portion of the non-display area NA may be bent to be invisible from the front surface of the display device. The non-display area NA may be also referred to as an edge area or a bezel area 1000.

For example, the driving circuit may be a circuit for driving the display panel, and include, but is not limited to, a data driving circuit and/or a gate driving circuit, and other circuit components, but the embodiments of the present disclosure are not limited thereto. Wires through which a control signal for controlling the driving circuits is supplied may be provided. For example, the control signal may include various timing signals including a clock signal, an input data enable signal, and synchronization signals, but the embodiments of the present disclosure are not limited thereto. The control signal may be received through the pad portion PAD. For example, link wires LL for transmitting signals may be positioned in the non-display area NA. For example, the pad portion PAD may be connected to driving components such as the flexible circuit board CB and the printed circuit board 160.

The non-display area NA may include a first non-display area NA1, a bending area BA, and a second non-display area NA2. The bending area BA may be disposed between the first non-display area NA1 and the second non-display area NA2. For example, the first non-display area NA1 may be an area that surrounds at least a portion of the display area AA. The bending area BA may be an area extending from at least one of the plurality of sides of the first non-display area NA1 and may be a bendable area. The second non-display area NA2 may be an area extending from the bending area BA, and the pad portion PAD may be positioned in the second non-display area NA2. For example, the bending area BA may be in a bent state and the remaining area of the substrate 110, excluding the bending area BA, may be in a flat state. In this case, as the bending area BA is in a bent state, the second non-display area NA2 may be positioned on the rear surface of the display area AA. However, the embodiments of the present disclosure are not limited thereto.

The display area AA of the substrate 110 or the display device 1000 may be configured in various shapes depending on the design of the display device 1000. For example, the display area AA may be configured in a rectangular shape with four rounded corners, but the embodiments of the present disclosure are not limited thereto. In another example, the display area AA may be configured in a rectangular shape with four right-angled corners, a circular shape, or the like, but the embodiments of the present disclosure are not limited thereto.

According to the present disclosure, the width of the second non-display area NA2 in which a plurality of pad electrodes PE are arranged may be greater than the width of the bending area BA in which only the plurality of link wires LL are arranged. Additionally, the width of the display area AA in which the plurality of sub-pixels are arranged may be greater than the width of the bending area BA in which only the plurality of link wires LL are arranged. For example, the width of the display area AA in which the plurality of sub-pixels are disposed may be greater than the width of the second non-display area NA2 in which a plurality of pad electrodes PE are disposed, and the embodiments of the present disclosure are not limited thereto. In the drawings, the width of the bending area BA is illustrated as being smaller than that of other areas of the substrate 110. However, the shape of the substrate 110 including the bending area BA is merely exemplary, and the embodiments of the present disclosure are not limited thereto.

Referring to FIG. 2, in the display device according to an exemplary embodiment of the present disclosure, a display area AA in which a plurality of pixels PX are disposed and a first non-display area NA1 surrounding the display area AA may be disposed.

Referring to FIG. 3, a plurality of pixel driving circuits PD may be arranged in the display area AA. The plurality of pixel driving circuits PD may be circuits for driving the micro-LEDs of the plurality of sub-pixels. Each of the plurality of pixel driving circuits PD may include a plurality of transistors including a driving transistor, a storage capacitor, and the like and may supply a control signal, power, and a driving current to the micro-LEDs of the plurality of sub-pixel to control the light emission operation of the plurality of micro-LEDs. For example, the pixel driving circuit PD may include a power wire and a signal wire for controlling the on/off state and/or light emission time of the micro-LED. For example, each of the plurality of pixel driving circuits PD may be a driving driver manufactured using a metal-oxide-silicon field effect transistor (MOSFET) fabrication process and disposed on a semiconductor substrate, but the embodiments of the present disclosure are not limited thereto. The driving driver may include the plurality of pixel driving circuits PD and may drive the plurality of sub-pixels. For example, each of the plurality of pixel driving circuits PD may include a micro driver (μDriver). However, embodiments of the present disclosure are not limited thereto. The micro driver may be implemented in a form of a chip. For example, each of the plurality of pixel driving circuits PD may include a driving chip. However, embodiments of the present disclosure are not limited thereto.

Referring also to FIG. 1, the flexible circuit board CB and the printed circuit board 160 may be positioned below the display panel 100. The flexible circuit board CB and the printed circuit board 160 may be positioned on at least one edge of the display panel 100, but the embodiments of the present disclosure are not limited thereto.

One side of the flexible circuit board CB may be attached to the display panel 100, and the other side thereof may be attached to the printed circuit board 160, but embodiments of the present disclosure are not limited thereto. The flexible circuit board CB may be a flexible film, but embodiments of the present disclosure are not limited thereto.

The pad portion PAD including the plurality of pad electrodes PE may be positioned in the second non-display area NA2. Driving components, including one or more flexible circuit boards (or flexible films) CB and the printed circuit board 160, may be attached or bonded to the pad portion PAD. The plurality of pad electrodes PE of the pad portion PAD may be electrically connected to the one or more flexible circuit boards (or flexible films) CB and may transmit various signals (or power) from the printed circuit board 160 and the flexible circuit board (or flexible film) CB to the plurality of pixel driving circuits PD of display area AA.

The flexible circuit board (or flexible film) CB may be a film in which various components are arranged on a base film having flexibility. For example, a driving integrated circuit (IC), such as a gate driver IC or a data driver IC, may be positioned on the flexible circuit board (or flexible film) CB, but the embodiments of the present disclosure are not limited thereto. For example, at least one of a gate driver IC or a data driver IC may be disposed in the display area AA of the display panel 100. For example, at least one of a gate driver IC or a data driver IC may be configured not to overlap with sub-pixels, or configured to overlap with one or more, or all, of the sub-pixels, or at least respective one or more portions of one or more sub-pixels. However, the embodiments of the present disclosure are not limited thereto.

The driving IC may be a component that processes data and a driving signal for displaying an image. The driving IC may be disposed by a method such as a chip-on-glass (COG) method, a chip-on-film (COF) method, a Chip On Panel (COP), or a tape carrier package (TCP) method depending on a method of being mounted, but embodiments of the present disclosure are not limited thereto. The flexible circuit board (or flexible film) CB may be attached to or bonded on the plurality of pad electrodes PE through a conductive adhesive layer, but embodiments of the present disclosure are not limited thereto.

The printed circuit board 160 may be a component electrically connected to one or more flexible circuit boards (or flexible films) CB and supplying signals to the driving IC. For example, the printed circuit board 160 may supply signals to the driving IC such as a gate driver IC or a data driver IC disposed on the flexible circuit board (or flexible film) CB. The printed circuit board 160 may be disposed at one side of the flexible circuit board (or flexible film) CB and electrically connected to the flexible circuit board (or flexible film) CB. Various components for supplying various signals to the driving IC may be disposed on the printed circuit board 160. For example, various components, such as a timing controller, a power supply unit, a memory, a processor, etc., may be disposed on the printed circuit board 160. For example, the printed circuit board 160 may include a power management integrated circuit (PMIC), but embodiments of the present disclosure are not limited thereto.

The printed circuit board 160 may include at least one hole 180 (see FIG. 1), but the embodiments of the present disclosure are not limited thereto. An internal component for sensing ambient light, temperature, or the like, which may be provided to a plurality of sensors, may be positioned in a region corresponding to the at least one hole 180. For example, the internal component may include an ambient light sensor (ALS), a temperature sensor, or the like, but the embodiments of the present disclosure are not limited thereto. For example, the hole 180 may be a transmission hole or the like, but the embodiments of the present disclosure are not limited thereto.

Referring to FIG. 1, the polarizing layer 293 may be positioned on the display panel 100. The polarizing layer 293 may prevent or reduce light generated from an external light source from entering the interior of the display panel 100 and affecting the micro-LEDs or the like. The polarizing layer 293 can prevent or alleviate external light reflection by components of the display panel 100.

The cover member 120 may be positioned on the polarizing layer 293. The cover member 120 may be a member for protecting the display panel 100. The adhesive layer 295 may be positioned between the polarizing layer 293 and the cover member 120. For example, the cover member 120 may be disposed on the polarizing layer 293 with the adhesive layer 295 disposed therebetween. The cover member 120 may be attached to the display panel 100 by using the adhesive layer 295. The adhesive layer 295 may include an optically clear adhesive (OCA), an optically clear resin (OCR), a pressure sensitive adhesive (PSA), or the like, but the embodiments of the present disclosure are not limited thereto.

The support substrate 110 may be positioned between the display panel 100 and the printed circuit board 160. The support substrate 110 may reinforce the rigidity of the display panel 100. The support substrate 110 may be a back plate, but the embodiments of the present disclosure are not limited thereto.

Referring to FIGS. 1 to 3, the plurality of link wires LL may be arranged in the first and second non-display areas NA1 and NA2. The plurality of link wires LL may be wires for transmitting various signals from the one or more flexible circuit boards (or flexible films) CB and the printed circuit board 160 to the display area AA. The plurality of link wires LL may extend from the plurality of pad electrodes PE of the second non-display area NA2 toward the bending area BA and the first non-display area NA1 and may be electrically connected to a plurality of driving wires VL of the display area AA.

The plurality of pixel driving circuits PD may be driven by receiving signals from one or more flexible circuit boards (or flexible films) CB and the printed circuit board 160 through the driving wiring VL in the display area AA and the link wiring LL in the non-display area NA.

For example, a plurality of driving wires VL may be wires for transmitting a signal output from the flexible circuit board (or flexible film) CB and the printed circuit board 160 together with a plurality of link wires LL to a plurality of pixel driving circuits PD. A plurality of driving wires VL may be disposed in the display area AA and electrically connected to each of a plurality of pixel driving circuits PD. A plurality of driving wires VL may extend from the display area AA toward the non-display area NA and may be electrically connected to a plurality of link wires LL.

Therefore, the signal output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, a portion of the plurality of link wires LL may also be bent together. For example, as the bending area BA is bent, a portion of each of the plurality of link wires LL may also be bent together. Stress may be concentrated on a portion of the bent link wires LL, thereby causing cracks in the link wires LL. Accordingly, the plurality of link wires LL may be formed of a highly flexible conductive material to reduce cracks when the bending area BA is bent. For example, the plurality of link wires LL may be formed of a highly flexible conductive material, such as gold (Au), silver (Ag), or aluminum (Al), but the embodiments of the present disclosure are not limited thereto.

Additionally, the plurality of link wires LL may be formed of one of various conductive materials used in the display area AA. For example, the plurality of link wires LL may be made of molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto. The plurality of link wires LL may have a multilayer structure made of various conductive materials. For example, the plurality of link wires LL may be composed of a triple layer structure. As one example, the plurality of link wires LL may have a triple-layer structure of titanium (Ti)/aluminum (Al)/titanium (Ti), but the embodiments of the present disclosure are not limited thereto.

A plurality of link wirings LL may be configured in various shapes to reduce stress. At least a portion of each of the plurality of link wirings LL disposed on the bending area BA may extend in the same direction as the extending direction of the bending area BA, or may extend in a direction different from the extending direction of the bending area BA to reduce stress. For example, when the bending area BA extends in one direction from the first non-display area NA1 to the second non-display area NA2, at least a portion of the link wiring LL disposed on the bending area BA may extend in a direction inclined with respect to the one direction, without being limited thereto.

In another example, at least a portion of each of the plurality of link lines LL may be configured in various shapes. For example, at least a portion of each of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal shape, a circular shape, and an omega (Ω) shape is repeatedly arranged, but embodiments of the present disclosure are not limited thereto.

Therefore, in order to minimize the stress concentrated on the plurality of link lines LL and the corresponding crack, the shape of the plurality of link lines LL may be formed in various shapes including the above-described shape, but embodiments of the present disclosure are not limited thereto.

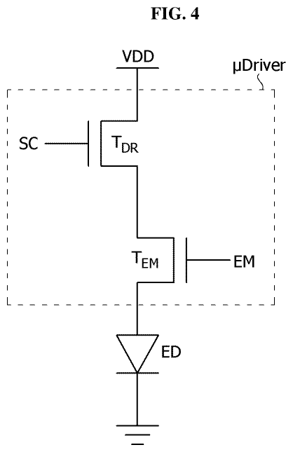

FIG. 4 is a diagram illustrating a circuit structure according to an exemplary embodiment of the present disclosure.

Although FIG. 4 illustrates that one light emitting element ED is connected to one micro-driver, the present disclosure is not limited thereto. Alternatively, a plurality of light emitting devices (EDs) may be connected to one micro driver. For example, eight light emitting elements ED may be connected to one micro-driver. For another example, 16 light emitting elements ED may be connected to one micro-driver, 32 light emitting elements ED or 64 light emitting elements ED or 256 light emitting elements ED or 768 light emitting elements ED may be connected to one micro-driver at the same time. The light emitting element ED may be a micro-light emitting device μLED. In another example, one micro driver μDriver may control a plurality of pixels arranged in a matrix (16×16) manner in the column direction and the row direction of the substrate. Each of the plurality of pixels may include a plurality of light emitting elements ED. For example, the micro driver μDriver may be configured to drive the plurality of light emitting elements ED.

One micro driver μDriver may include a driving transistor T_{DR} and a light emitting transistor T_{EM}, but embodiments of the present disclosure are not limited thereto. For example, the micro driver μDriver may further include at least one capacitor. For example, the driving transistor T_{DR} may be configured to drive plurality of light emitting elements ED. One micro driver μDriver may be implemented in a form of a chip.

For example, in the driving transistor T_{DR}, a high potential power voltage VDD may be applied to the first electrode of the driving transistor T_{DR}, a first electrode of the light emitting transistor T_{EM} may be connected to the second electrode of the driving transistor T_{DR}, and a scan signal SC may be applied to the gate electrode of the driving transistor T_{DR}. The scan signal SC applied to the gate electrode of the driving transistor T_{DR} is a direct current power source, and a fixed reference voltage Vref may be applied to each frame, but embodiments of the present disclosure are not limited thereto. The driving transistor T_{DR} may be turned on or off in response to the scan signal SC applied to the gate electrode of the driving transistor T_{DR}.

In the light emitting transistor T_{EM}, the second electrode of the driving transistor TDR is connected to the first electrode of the light emitting transistor T_{EM}, the light emitting element ED is connected to the second electrode of the light emitting transistor T_{EM}, and the light emitting signal EM may be applied to the gate electrode of the light emitting transistor T_{EM}. The light emitting signal EM applied to the gate electrode of the light emitting transistor T_{EM} may be a pulse width modulation signal that changes every frame, but embodiments of the present disclosure are not limited thereto. The light emitting transistor T_{EM} may be turned on or off in response to the light emitting signal EM applied to the gate electrode of the light emitting transistor T_{EM}.

In the light emitting element ED, the first electrode may be connected to the second electrode of the light emitting transistor T_{EM}, and the second electrode may be connected to the ground. For example, the first electrode may be an anode electrode and the second electrode may be a cathode electrode, but configurations of the present disclosure are not limited thereto.

Each of the transistors included in the micro driver μDriver may be an n-type transistor or a p-type transistor. For example, each of the driving transistor T_{DR} and the light emitting transistor TEM may be an n-type transistor or a p-type transistor.

In the micro driver μDR, the driving transistor T_{DR} may be turned on by the scan signal SC applied from the timing controller T-CON, and the light emitting transistor T_{EM} may be turned on by the light emitting signal EM. As a result, when the driving transistor T_{DR} and the light emitting transistor T_{EM} are turned on, the driving current is applied to the light emitting element ED via the driving transistor T_{DR} and the light emitting transistor T_{EM} by the high potential power voltage VDD applied to the first electrode of the driving transistor T_{DR}, and thus the light emitting element ED may emit light.

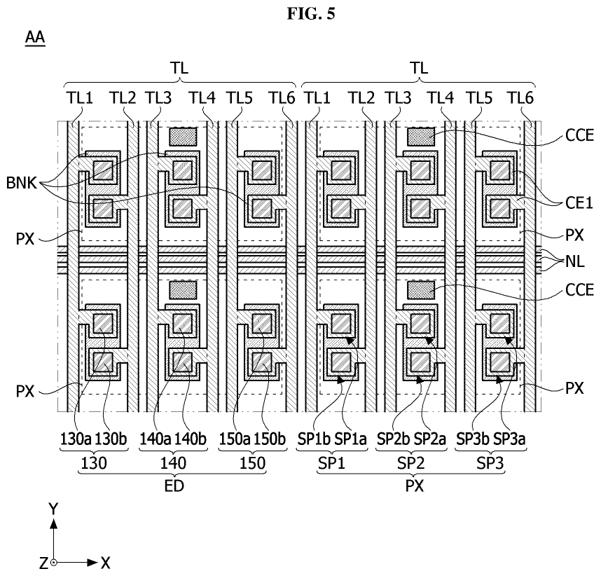

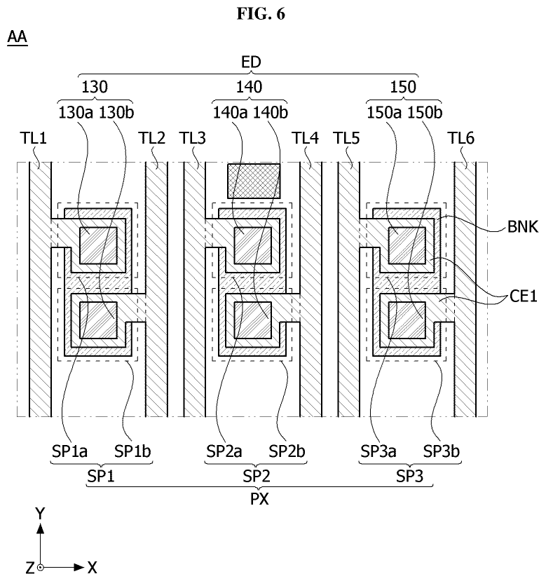

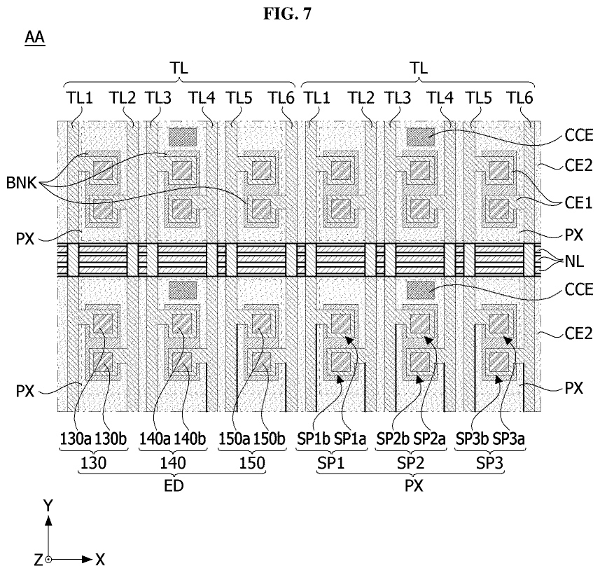

FIGS. 5 to 7 are plan views of a display device according to an exemplary embodiment of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels.

In FIGS. 5 and 6, a plurality of signal lines TL, a plurality of communication lines NL, a plurality of first electrodes CE1, a plurality of banks BNK, and a plurality of light emitting elements ED are illustrated, but embodiments of the present disclosure are not limited thereto. FIG. 7 is an enlarged plan view in which a plurality of second electrodes CE2 are additionally disposed in FIG. 6.

Referring to FIGS. 5 and 6, a plurality of pixels PX including a plurality of sub-pixels may be disposed in the display area AA. Each of the plurality of sub-pixels includes a light emitting element ED and may independently emit light. The plurality of sub-pixels may form a plurality of rows and a plurality of columns and may be arranged in a matrix form, but configurations of the present disclosure are not limited thereto.

A plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, the other may be a green sub-pixel, and the rest may be a blue sub-pixel. Types of a plurality of sub-pixels are examples, and embodiments of the present disclosure are not limited thereto.

In another exemplary embodiment, any one of the first sub-pixel SP1, the second sub-pixel SP2, and the third sub-pixel SP3 may be a cyan sub-pixel, the other may be a magenta sub-pixel, and the rest may be a yellow sub-pixel. In yet another exemplary embodiment, each of the first sub-pixel SP1, the second sub-pixel SP2, and the third sub-pixel SP3 may be red, green, blue or white sub-pixel. Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a 1-1 sub-pixel SP1a and a 1-2 sub-pixel SP1b. The pair of second sub-pixels SP2 may include a 2-1 sub-pixel SP2a and a 2-2 sub-pixel SP2b.

The pair of third sub-pixels SP3 may include a 3-1 sub-pixel SP3a and a 3-2 sub-pixel SP3b. For example, one pixel PX may include a 1-1 sub-pixel SP1a, a 1-2 sub-pixel SP1b, a 2-1 sub-pixel SP2b, a 3-1 sub-pixel SP3a, and a 3-2 sub-pixel SP3b, but embodiments of the present disclosure are not limited thereto. More or less sub-pixels can be included in the one pixel PX.

A plurality of sub-pixels constituting one pixel PX may be variously arranged. For example, in one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of a plurality of sub-pixels constituting one pixel PX are exemplary, and configurations of the present disclosure are not limited thereto.

For example, in one pixel PX, a 1-1 sub-pixel SP1a and a 1-2 sub-pixel SP1b may be disposed in the same column, a 2-1 sub-pixel SP2a and a 2-2 sub-pixel SP2b may be disposed in the same column, and a 3-1 sub-pixel SP3a and a 3-2 sub-pixel SP3b may be disposed in the same column, and the embodiments of the present disclosure are not limited thereto.

A plurality of signal lines TL may be disposed in a region between the plurality of sub-pixels. The plurality of signal lines TL may extend in a column direction between adjacent ones of the plurality of sub-pixels. The plurality of signal lines TL may be lines that transmit an anode voltage from the pixel driving circuit PD to a plurality of sub-pixels. For example, the plurality of signal lines TL may be electrically connected to the plurality of pixel driving circuits PD and the first electrode CE1 of the plurality of sub-pixels.

The anode voltage output from the pixel driving circuit PD may be transferred to the first electrodes CE1 of a plurality of sub-pixels through a plurality of signal lines TL. For example, the first electrode CE1 may be an electrode electrically connected to the anode electrode 134 of the light emitting element ED. Accordingly, the anode voltage from the signal line TL may be transferred to the anode electrode 134 of the light emitting element ED through the first electrode CE1.

Accordingly, instead of forming a plurality of transistors and storage capacitors in each of the plurality of sub-pixels, the structure of the display device 1000 may be simplified by using the pixel driving circuit PD in which the plurality of pixel circuits are integrated with each other. Also, as circuits disposed in each of the plurality of sub-pixels are integrated in one pixel driving circuit PD, high efficiency and low power driving of the display device 1000 may be possible.

A plurality of signal lines TL may include a first signal line TL1, a second signal line TL2, a third signal line TL3, a fourth signal line TL4, a fifth signal line TL5 and a sixth signal line TL6. Each of the first signal line TL1 and the second signal line TL2 may be electrically connected to each of a pair of first sub-pixels SP1. The third signal line TL3 and the fourth signal line TL4 may be electrically connected to each of a pair of second sub-pixels SP2. The fifth signal line TL5 and the sixth signal line TL6 may be electrically connected to each of a pair of third sub-pixels SP3.

The first signal line TL1 and the second signal line TL2 may be electrically connected to the pair of first sub-pixels SP1. The first signal wire TL1 may be positioned on one side of the pair of first sub-pixels SP1, and the second signal wire TL2 may be positioned on another side of the pair of first sub-pixels SP1. The first signal wire TL1 may be electrically connected to the first electrode CE1 of one, e.g., the 1-1 sub-pixel SP1a, of the pair of first sub-pixels SP1. The second signal wire TL2 may be electrically connected to the first electrode CE1 of the other, e.g., the 1-2 sub-pixel SP1b, of the pair of first sub-pixels SP1.

The third signal line TL3 and the fourth signal line TL4 may be electrically connected to the pair of second sub-pixels SP2. The third signal wire TL3 may be positioned on one side of the pair of second sub-pixels SP2, and the fourth signal wire TL4 may be positioned on another side of the pair of second sub-pixels SP2. For example, the third signal wire TL3 may be positioned adjacent to the second signal wire TL2. The third signal wire TL3 may be electrically connected to the first electrode CE1 of one, e.g., the 2-1 sub-pixel SP2a, of the pair of second sub-pixels SP2. The fourth signal wire TL4 may be electrically connected to the first electrode CE1 of the other, e.g., the 2-2 sub-pixel SP2b, of the pair of second sub-pixels SP2.

The fifth signal line TL5 and the sixth signal line TL6 may be electrically connected to the pair of third sub-pixels SP3. The fifth signal wire TL5 may be positioned on one side of the pair of third sub-pixels SP3, and the sixth signal wire TL6 may be positioned on another side of the pair of third sub-pixels SP3. For example, the fifth signal wire TL5 may be positioned adjacent to the fourth signal wire TL4. The sixth signal wire TL6 may be positioned adjacent to the first signal wire TL1, which is connected to an adjacent pixel PX. The fifth signal wire TL5 may be electrically connected to the first electrode CE1 of one, e.g., the 3-1 sub-pixel SP3a, of the pair of third sub-pixels SP3. The sixth signal wire TL6 may be electrically connected to the first electrode CE1 of the other, e.g., the 3-2 sub-pixel SP3b, of the pair of third sub-pixels SP3.

For example, the first signal line TL1 and the second signal line TL2 may be electrically connected to the 1-1 sub-pixel SP1a and the 1-2 sub-pixel SP1b, respectively, the third signal line TL3 and the fourth signal line TL4 may be electrically connected to the 2-1 sub-pixel SP2a and the 2-2 sub-pixel SP2b, respectively, and the fifth signal line TL5 and the sixth signal line TL6 may be electrically connected to the 3-1 sub-pixel SP3a and the 3-2 sub-pixel SP3b, respectively, and the embodiments of the present disclosure are not limited thereto.

The plurality of signal wires TL may be made of a conductive material. For example, the plurality of signal wires TL may be formed of a conductive material, such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the plurality of signal wires TL may have a multilayer structure made of a conductive material. For example, the plurality of signal wires TL may have a multilayer structure of titanium (Ti)/aluminum (Al)/titanium (Ti)/indium tin oxide (ITO), but the embodiments of the present disclosure are not limited thereto.

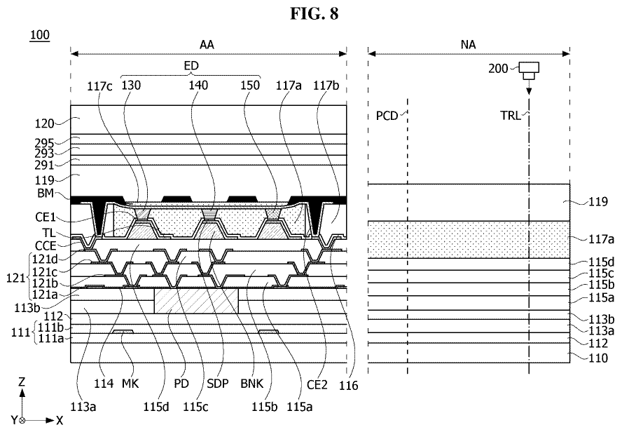

The plurality of communication wires NL may be arranged in a region between adjacent ones of the plurality of pixels PX. The plurality of communication wires NL may extend in a row direction in the region between adjacent ones of the plurality of pixels PX. The plurality of communication wires NL may be arranged in a region between adjacent ones of the plurality of second electrodes (CE2 in FIG. 8), and may not overlap the plurality of second electrodes CE2. For example, the plurality of communication wires NL may be wires used for short-range communication, such as near field communication (NFC). The plurality of communication wires NL may function as an antenna. For example, the plurality of communication wires NL may be a plurality of connection wires or the like, but the embodiments of the present disclosure are not limited thereto.

According to the present disclosure, the bank BNK may be positioned in each of the plurality of sub-pixels. The plurality of banks may be structures on which the plurality of micro-LEDs are mounted. The plurality of banks may guide the positions of the plurality of micro-LEDs ED in a transfer process for transferring the plurality of micro-LEDs ED to the display device 1000. During the transfer process of the plurality of micro-LEDs ED, the plurality of micro-LEDs ED may be transferred onto the plurality of banks BNK. The plurality of banks BNK may be bank patterns or structures, but embodiments of present disclosure are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated from each other. Accordingly, the banks BNK of the first sub-pixel SP1, the second sub-pixel SP2, and the third sub-pixel SP3, onto which different types of micro-LEDs ED are transferred, may be easily distinguished.

The bank BNK of the 1-1 sub-pixel SP1a and the bank BNK of the 1-2 sub-pixel SP1b may be connected to each other or may be formed to be spaced apart from each other. For example, a bank BNK of the 1-1 sub-pixel SP1a in which the same type of light emitting element ED is disposed and a bank BNK of the 1-2 sub-pixel SP1b may be connected to each other or may be spaced apart from each other or separated from each other in consideration of a design such as a transfer process requirement and the like. In addition, the bank BNK of the 2-1 sub-pixel SP2a and the bank BNK of the 2-2 sub-pixel SP2b may be connected to each other or may be formed to be spaced apart from each other. In addition, the bank BNK of the 3-1 sub-pixel SP3a and the bank BNK of the 3-2 sub-pixel SP3b may be connected to each other or may be formed to be spaced apart from each other.

Accordingly, the bank BNK of the pair of first sub-pixels SP1, the bank BNK of the pair of second sub-pixels SP2, and the bank BNK of the pair of third sub-pixels SP3 may be variously formed, and embodiments of the present disclosure are not limited thereto.

For example, the plurality of banks BNK may be formed of an organic insulating material such as acryl resin, epoxy resin, phenolic resin, polyamide resin, and/or polyimide resin, etc. Alternatively, the bank BNK may include an inorganic insulating material such as silicon nitride, aluminum nitride, zirconium nitride, titanium nitride, hafnium nitride, tantalum nitride, silicon oxide, aluminum oxide, or titanium oxide, etc. The plurality of banks BNK may be configured as a single layer or a multi-layer of the organic insulating material. For example, the plurality of banks BNK may be formed of a photoresist, polyimide (PI), or acryl-based material, but the embodiments of present disclosure are not limited thereto. The plurality of banks BNK may be configured as a single layer or a multi-layer of the inorganic insulating material. Also, the bank BNK may include a black dye.

The first electrode CE1 may be positioned in each of the plurality of sub-pixels. The first electrode CE1 may be positioned on the bank BNK. The first electrode CE1 may be disposed on the bank BNK. For example, the first electrodes CE1 may be positioned on the top and side surfaces of the plurality of banks BNK.

At least a portion of the first electrode CE1 may extend outside of the bank BNK and be electrically connected to the signal wire TL closest to the first electrode CE1. For example, a portion of the first electrode CE1 of the 1-1 sub-pixel SP1a may extend to one side region of the 1-1 sub-pixel SP1a and be electrically connected to the first signal wire TL1, and a portion of the first electrode CE1 of the 1-2 sub-pixel SP1b may extend to the opposite side region of the 1-2 sub-pixel SP1b and be electrically connected to the second signal wire TL2.

A portion of the first electrode CE1 of the 2-1 sub-pixel SP2a may extend to one side area of the 2-1 sub-pixel SP2a to be electrically connected to the third signal line TL3, and a portion of the first electrode CE1 of the 2-2 sub-pixel SP2b may extend to the other side area of the 2-2 sub-pixel SP2b to be electrically connected to the fourth signal line TL4. A portion of the first electrode CE1 of the 3-1 sub-pixel SP3a may extend to one side area of the 3-1 sub-pixel SP3a to be electrically connected to the fifth signal line TL5, and a portion of the first electrode CE1 of the 3-2 sub-pixel SP3b may extend to the other side area of the 3-2 sub-pixel SP3b to be electrically connected to the sixth signal line TL6.

The first electrode CE1 may be electrically connected to the anode electrode 134 of the micro-LED ED, and may transmit the anode voltage from the pixel driving circuit PD to the micro-LED ED of each of the plurality of sub-pixels through the signal wire TL. Different voltages may be applied to the respective first electrodes CE1 of the plurality of sub-pixels according to an image to be displayed. For example, different voltages may be applied to the plurality of sub-pixels. For example, different voltages may be applied to the respective first electrodes CE1 of each of the plurality of sub-pixels. Accordingly, the first electrode CE1 may be a pixel electrode, and the embodiments of the present disclosure are not limited thereto.

The first electrode CE1 may be formed of a conductive material. For example, the first electrode CE1 may be formed integrally with a plurality of signal lines TLs. For example, the first electrode CE1 may be formed of the same conductive material as a plurality of signal lines TLs, but embodiments of the present disclosure are not limited thereto. For example, the first electrode CE1 may be formed of a multi-layered structure of titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but embodiments of the present disclosure are not limited thereto. For another example, the first electrode CE1 may be formed of a multi-layered structure of a conductive material. For example, a plurality of first electrodes CE1 may be formed of a multi-layered structure of titanium (Ti)/aluminum (Al)/titanium (Ti)/indium tin oxide (ITO), but embodiments of the present disclosure are not limited thereto.

For example, the first electrode CE1 may have a multilayer structure including a transparent conductive film and an opaque conductive film having high reflective efficiency. The transparent conductive film may be made of a material having a relatively high work function value such as indium-tin-oxide (ITO) or indium-zinc-oxide (IZO), and the opaque conductive film may have a single-layer or multi-layer structure including Al, Ag, Cu, Pb, Mo, Ti or an alloy thereof. However, the embodiments of the present disclosure are not limited thereto. A light emitting element ED may be disposed in each of a plurality of sub-pixels. A plurality of light emitting elements ED may be any one of a light-emitting diode (LED) and a micro light-emitting diode (Micro LED), but embodiments of the present disclosure are not limited thereto. A plurality of light emitting elements ED may be disposed on the bank BNK and the first electrode CE1. A plurality of light emitting elements ED may be disposed on the first electrode CE1 and may be electrically connected to the first electrode CE1. Accordingly, the light emitting element ED may emit light by receiving the anode voltage from the pixel driving circuit PD through the signal line TL and the first electrode CE1.

The plurality of micro-LEDs ED may include a first micro-LED 130, a second micro-LED 140, and a third micro-LED 150. As one example, the plurality of micro-LEDs ED may include, for example, the first micro-LED 130 for red light emission, the second micro-LED 140 for green light emission, and the third micro-LED 150 for blue light emission. The first micro-LED 130 may have a size larger than a size of each of the second micro-LED 140 and the third micro-LED 150, but is not limited thereto.

The first micro-LED 130 may be positioned in the first sub-pixel SP1. The second micro-LED 140 may be positioned in the second sub-pixel SP2. The third micro-LED 150 may be positioned in the third sub-pixel SP3. For example, one of the first micro-LED 130, the second micro-LED 140, and the third micro-LED 150 may be a red micro-LED, another one may be a green micro-LED, and the remaining one may be a blue micro-LED, but the embodiments of the present disclosure are not limited thereto. Accordingly, by combining red light, green light, and blue light emitted from the plurality of micro-LEDs ED, various colors of light including white may be implemented. The types of the plurality of micro-LEDs ED are merely exemplary, and the embodiments of the present disclosure are not limited thereto.

In another exemplary embodiment, one of the first micro-LED 130, the second micro-LED 140, and the third micro-LED 150 may be a cyan micro-LED, the other may be a magenta micro-LED, and the rest may be a yellow micro-LED. In yet another exemplary embodiment, each of the first micro-LED 130, the second micro-LED 140, and the third micro-LED 150 may be red, green, blue or white micro-LED.

The first light emitting device 130 may include a plurality of the light-emitting elements disposed in the pair of first sub-pixels SP1, the second light emitting device 140 may include plurality of the light-emitting elements disposed in the pair of second sub-pixels SP2, and the third light emitting device 150 may include a plurality of the light-emitting elements disposed in the pair of third sub-pixels SP3. However, embodiments of the present disclosure are not limited thereto.

The first light emitting device 130 may include a 1-1 light emitting device 130a disposed in the 1-1 sub-pixel SP1a and a 1-2 light emitting device 130b disposed in the 1-2 sub-pixel SP1b. The second light emitting device 140 may include a 2-1 light emitting device 140a disposed in the 2-1 sub-pixel SP2a and a 2-2 light emitting device 140b disposed in the 2-2 sub-pixel SP2b. The third light emitting device 150 may include a 3-1 light emitting device 150a disposed in the 3-1 sub-pixel SP3a and a (3-2 light emitting device 150b) disposed in the (3-2 sub-pixel SP3b).

Referring to FIGS. 5 to 7, the second electrode CE2 may be positioned in each of the plurality of sub-pixels. The second electrode CE2 may be positioned on the micro-LED ED. The second electrode CE2 may be electrically connected to the pixel driving circuit PD through the plurality of contact electrodes CCE.

For example, the second electrode CE2 may be electrically connected to a cathode electrode 135 of the micro-LED ED and may transmit a cathode voltage from the pixel driving circuit PD to the micro-LED ED. The same cathode voltage may be applied to the second electrode CE2 of each of the plurality of sub-pixels. For example, the same voltage may be applied to the second electrode CE2 of each of the plurality of sub-pixels and the cathode electrode 135 of the micro-LED ED. Accordingly, the second electrode CE2 may be a common electrode, but the embodiments of the present disclosure are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, the second electrodes CE2 of at least some sub-pixels may be shared. For example, the second electrodes CE2 of at least some of the plurality of pixels PX arranged in the same row may be connected to each other. For example, a single second electrode CE2 may be provided for the plurality of pixels PX. One second electrode CE2 may be provided for every n sub-pixels.

For example, some of the second electrodes CE2 of the plurality of sub-pixels may be spaced apart or separated from each other. For example, the second electrode CE2 connected to the pixels PX in an nth row and the second electrode CE2 connected to the pixels PX in an (n+1)th row may be spaced apart or separated from each other. For example, adjacent ones of the plurality of second electrodes CE2 may be spaced apart from each other with the plurality of communication wires NL, which extend in the row direction, interposed therebetween. Accordingly, the number of the plurality of sub-pixels may be greater than the number of the plurality of second electrodes CE2. In another example, all of the second electrodes CE2 of the plurality of sub-pixels may be connected to each other, such that only one second electrode CE2 may be disposed on the substrate 110. However, embodiments of the present disclosure are not limited thereto.

The plurality of second electrodes CE2 may be made of a transparent conductive material, but the embodiments of the present disclosure are not limited thereto. The plurality of second electrodes CE2 may be made of a transparent conductive material, allowing light emitted from the micro-LED ED to be directed upward through the second electrode CE2. For example, the second electrode CE2 may be made of a transparent conductive material such as indium tin oxide (ITO), indium zinc oxide (IZO), or indium gallium zinc oxide (IGZO), but the embodiments of the present disclosure are not limited thereto.

For example, the second electrode CE2 may have a multilayer structure including a transparent conductive film and an opaque conductive film having high reflective efficiency. The transparent conductive film may be made of a material having a relatively high work function value such as indium-tin-oxide (ITO) or indium-zinc-oxide (IZO), and the opaque conductive film may have a single-layer or multi-layer structure including Al, Ag, Cu, Pb, Mo, Ti or an alloy thereof. However, the embodiments of the present disclosure are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be positioned between the substrate 110 and the plurality of second electrodes CE2 and may transmit the cathode voltage from the pixel driving circuit PD to the second electrodes CE2.

For example, when using a micro-LED as the micro-LED ED, a plurality of micro-LEDs may be formed on a wafer and transferred to the substrate 110 of the display device 1000 to fabricate the display device 1000. In the process of transferring the plurality of micro-LEDs ED having a fine size from the wafer to the substrate 110, various defects may occur. For example, in some sub-pixels, a transfer failure may occur where the micro-LED ED is not transferred, and in some other sub-pixels, a defect may occur where the micro-LED ED is transferred to an incorrect position due to an alignment error. Additionally, even if the transfer process is normally performed, the transferred micro-LED ED itself may be defective. Therefore, in the transfer process of the plurality of micro-LEDs ED, in consideration of defects, a plurality of micro-LEDs ED that emit light of the same color may be transferred onto one sub-pixel. A lighting test may be performed on the plurality of micro-LEDs ED and only one micro-LED ED that is finally determined to be normal or non-defective may be used.

For example, a 1-1 micro-LED 130a and a 1-2 micro-LED 130b may be transferred together onto one pixel PX, and their defect states may be inspected. If both the 1-1 micro-LED 130a and the 1-2 micro-LED 130b are determined to be normal or non-defective, the 1-1 micro-LED 130a may be used and the 1-2 micro-LED 130b may remain unused. However, embodiments of the present disclosure are not limited thereto. For example, when both the 1-1 micro-LED 130a and the 1-2 micro-LED 130b are determined to be normal or non-defective, the 1-1 micro-LED 130a may not be used, and the 1-2 micro-LED 130b may be used. In another example, if, among the 1-1 micro-LED 130a and the 1-2 micro-LED 130b, the 1-2 micro-LED 130b is determined to be normal or non-defective, the 1-1 micro-LED 130a may remain unused and only the 1-2 micro-LED 130b may be used. Accordingly, even if a plurality of micro-LEDs ED that emit light of the same color are transferred onto one pixel PX, ultimately, only one of the micro-LEDs ED may be used.

Thus, in a pair of micro-LEDs ED, one may be a main (or primary) micro-LED ED, while the other may be a redundancy micro-LED ED or a spare light-emitting element ED. The redundancy micro-LED ED may be an extra micro-LED ED that is transferred to cope with a defect in the main micro-LED ED. The redundant micro-LED may be used as a replacement in the event of a failure of the main micro-LED. When the main micro-LED ED is defective, the main micro-LED ED may be replaced with the redundant micro-LED ED. Thus, by transferring both the main micro-LED ED and the redundancy micro-LED ED to one pixel PX, degradation in display quality due to defects in the main micro-LED ED or the redundancy micro-LED ED may be minimized or reduced.

For example, the 1-1 light emitting device 130a, the 2-1 light emitting device 140a, and the 3-1 light emitting device 150a transferred to one pixel PX may be used as the main light emitting element ED, and the 1-2 light emitting device 130b, the 2-2 light emitting device 140b, and the 3-2 light emitting device 150b may be used as the redundancy light emitting element ED. In case of the failure of the 1-1 light emitting device 130a, the 2-1 light emitting device 140a, and the 3-1 light emitting device 150a, the 1-2 light emitting device 130b, the 2-2 light emitting device 140b, and the 3-2 light emitting device 150b can be used as a replacement for it.

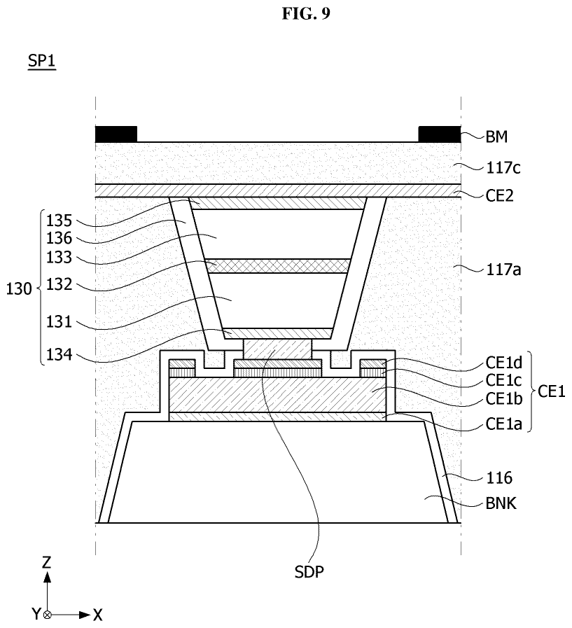

FIG. 8 is a cross-sectional view of a display device according to an exemplary embodiment of the present disclosure. FIG. 9 is an enlarged cross-sectional view of a display device according to an exemplary embodiment of the present disclosure. For example, FIG. 8 is a cross-sectional view of the display area AA, the first and second non-display areas NA1 and NA2, and the bending area BA.

Referring to FIG. 8, a buffer layer 111 may be disposed in the remaining area of the substrate 110 except for the bending area BA. The buffer layer 111 may include a first buffer layer 111a and a second buffer layer 111b, without being limited thereto. More or less buffer layers may be included.

The first buffer layer 111a and the second buffer layer 111b may be positioned in the display area AA, but may be not disposed in the first non-display area NA1 and the second non-display area NA2 and may not be arranged in the entirety or part of the bending area BA, but the embodiments of the present disclosure are not limited thereto.

The first buffer layer 111a and the second buffer layer 111b may reduce the permeation of moisture or impurities through the substrate 110. The first buffer layer 111a and the second buffer layer 111b may be made of an inorganic insulating material. For example, the first buffer layer 111a and the second buffer layer 111b may be configured as a single layer or multi-layer of silicon oxide (SiOx) or silicon nitride (SiNx), but the embodiments of the present disclosure are not limited thereto.

In addition, in order to prevent or at least reduce moisture permeation penetrating from the non-display area NA, the buffer layer 111 may be disposed only in the display area AA. The present disclosure is not limited thereto.

The non-display area NA may include a first non-display area NA1, a bending area BA, and a second non-display area NA2.

For example, the buffer layer 111 may be formed of a single layer or multiple layers of silicon oxide (SiOx) or silicon nitride (SiNx), which is an inorganic film material, but embodiments of the present disclosure are not limited thereto. For example, portions of the first buffer layer 111a and the second buffer layer 111b on the bending area BA may be removed. The upper surface of the substrate 110 located in the bending area BA may be exposed from the first buffer layer 111a and the second buffer layer 111b. By removing the first buffer layer 111a and the second buffer layer 111b made of the inorganic insulating material from the bending area BA, cracks in the first buffer layer 111a and the second buffer layer 111b that may occur during bending may be minimized or reduced.

A plurality of alignment keys MK may be arranged between the first buffer layer 111a and the second buffer layer 111b. The plurality of alignment keys MK may be configured to identify the position of the pixel driving circuit PD during the fabricating process of the display device 1000. For example, the plurality of alignment keys MK may be configured to align the position of the pixel driving circuit PD transferred onto an adhesive layer 112. In another example, the plurality of alignment keys MK may be omitted or briefly given.

The adhesive layer 112 may be positioned on the second buffer layer 111b. The adhesive layer 112 may be positioned in the display area AA, the first non-display area NA1, the bending area BA, and the second non-display area NA2. In another example, at least a portion of the adhesive layer 112 may be removed from the non-display area NA that includes the bending area BA. For example, the adhesive layer 112 may be made of any one of an adhesive polymer, epoxy resin, UV-curable resin, a polyimide-based material, an acrylate-based material, a urethane-based material, or polydimethylsiloxane (PDMS), but the embodiments of the present disclosure are not limited thereto.

In the display area AA, the pixel driving circuit PD may be positioned on the adhesive layer 112. When the pixel driving circuit PD is implemented as a driving driver, the driving driver may be mounted on the adhesive layer 112 through a transfer process, but the embodiments of the present disclosure are not limited thereto.

A protective layer may be disposed on the adhesive layer 112 and surround the pixel driving circuit PD. The protective layer may include a first protective layer 113a and a second protective layer 113b, but is not limited thereto. More or less protective layer may be included. In some cases, at least one additional protection layer may be further included.

A first protective layer 113a and a second protective layer 113b may be positioned on the top or side surfaces of the adhesive layer 112 and the pixel driving circuit PD. The first protective layer 113a and the second protective layer 113b may be positioned to surround the side surface of the pixel driving circuit PD, but the embodiments of the present disclosure are not limited thereto. For example, the second protective layer 113b may be positioned to cover at least a portion of the top surface of the pixel driving circuit PD. For example, at least one of the first protective layer 113a and the second protective layer 113b positioned in the bending area BA may be omitted or briefly given.

For example, the first protective layer 113a may be entirely positioned over the display area AA and the non-display area NA, and the second protective layer 113b may be partially positioned over the display area AA, the first non-display area NA1, and the second non-display area NA2. For example, a portion of the second protective layer 113b in the bending area BA may be removed. However, the embodiments of the present disclosure are not limited thereto.

The first protective layer 113a and the second protective layer 113b may be formed of an organic insulating material, but the embodiments of the present disclosure are not limited thereto. For example, at least one of the first protective layer 113a and the second protective layer 113b may be made of an organic insulating material (i.e., organic layer). For example, the first protective layer 113a and the second protective layer 113b may be formed of photoresist, polyimide (PI), or a photoacryl-based material, but the embodiments of the present disclosure are not limited thereto. For example, the first protective layer 113a and the second protective layer 113b may be an overcoating layer or an insulating layer, but the embodiments of the present disclosure are not limited thereto.

According to the present disclosure, a plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected to the plurality of signal wires TL, the plurality of contact electrodes CCE, and the like through the plurality of first connection wires 121. For example, the plurality of first connection wires 121 may include a 1-1 connection wire 121a, a 1-2 connection wire 121b, a 1-3 connection wire 121c, and a 1-4 connection wire 121d, and the 1-1 connection wire 121a, the 1-2 connection wire 121b, the 1-3 connection wire 121c, and the 1-4 connection wire 121d may be electrically connected to each other through contact holes formed in insulating layers between the connection wires, but the embodiments of the present disclosure are not limited thereto.

Among them, the 1-1 connection wire 121a may be a base metal line M0, the 1-2 connection wire 121b may be a first metal line M1, the 1-3 connection wire 121c may be a second metal line M2, the 1-4 connection wire 121d may be a third metal line M3, and the contact electrode CCE may be a fourth metal line M4. For example, a 1-1 connection wire 121a, a 1-2 connection wire 121b, a 1-3 connection wire 121c, and a 1-4 connection wire 121d may be arranged in different metal layers.

For example, a plurality of 1-1 connection wirings 121a may be disposed on the second protective layer 113b. A plurality of 1-1 connection wirings 121a may be electrically connected to the pixel driving circuit PD. A plurality of 1-1 connection wirings 121a may transfer voltages output from the pixel driving circuit PD to the first electrode CE1 or the second electrode CE2.

For example, the first and second protective layers 113a and 113b may be formed of an organic insulating material. For example, the first and second protective layers 113a and 113b may be formed of a photo resist, polyimide (PI), a photoacryl-based material, or the like, but embodiments of the present disclosure are not limited thereto. For example, the first protective layer 113a and the second protective layer 113b may be formed of the same material. Embodiments of the present disclosure are not limited thereto. Alternatively, t the first protective layer 113a and the second protective layer 113b may be formed of a different insulating material. For example, the first protective layer 113a and the second protective layer 113b may be insulating layers, but embodiments of the present disclosure are not limited thereto.

In addition, the first insulating layer 114 may be disposed on the second protective layer 113b. For example, the first insulating layer 114 may be disposed to cover the second protective layer 113b. For example, the first insulating layer 114 may be disposed in the entire display area AA and the non-display area NA. For example, the first insulating layer 114 may be formed of a single layer or multiple layers of silicon oxide (SiOx) or silicon nitride (SiNx), which is an inorganic film material, but embodiments of the present disclosure are not limited thereto.

For example, the first protective layer 113a, the second protective layer 113b, and the first insulating layer 114 may be made of the same material. Embodiments of the present disclosure are not limited thereto. Alternatively, the first protective layer 113a, the second protective layer 113b, and the first insulating layer 114 may be composed of a different insulating material. However, the embodiments of the present disclosure are not limited thereto.

For example, as shown in FIG. 8, in order to prevent moisture permeation from penetrating from the non-display area NA, the first insulating layer 114 may be disposed in the display area AA without being disposed in the non-display area NA. The present disclosure is not limited thereto. For example, the first insulating layer 114 may be disposed on the second protective layer 113b in the display area AA, but is not limited thereto.

A first organic insulating layer 115a may be disposed on the first insulating layer 114. The first organic insulating layer 115a may be formed of an organic insulating material, but embodiments of the present disclosure are not limited thereto. For example, the first organic insulating layer 115a may be formed of a photo resist, polyimide (PI), a photoacryl-based material, or the like, but embodiments of the present disclosure are not limited thereto.

In addition, a plurality of 1-2 connection wirings 121b may be disposed on the first organic insulating layer 115a. A plurality of 1-2 connection wirings 121b may be connected to or directly connected to the pixel driving circuit PD. For example, a portion of the 1-2 connection wiring 121b may be directly or indirectly connected to the pixel driving circuit PD through a contact hole of the first insulating layer 114. Another portion of the 1-2 connection wiring 121b may be electrically connected to the 1-1 connection wiring 121a through a contact hole of the first insulating layer 114. However, embodiments of the present disclosure are not limited thereto. The voltage output from the pixel driving circuit PD may be transferred to the first electrode CE1 or the second electrode CE2 through connection wirings different from a plurality of 1-2 connection wirings 121b.

The second organic insulating layer 115b may be positioned on the plurality of 1-2 connection wires 121b. For example, the second organic insulating layer 115b may be disposed to cover the plurality of 1-2 connection wires 121b. The second organic insulating layer 115b may be entirely positioned over the display area AA and the non-display area NA, but the embodiments of the present disclosure are not limited thereto. The second organic insulating layer 115b may be made of an organic insulating material, but the embodiments of the present disclosure are not limited thereto. For example, the first organic insulating layer 115a may be made of photoresist, polyimide (PI), or a photoacryl-based material, but the embodiments of the present disclosure are not limited thereto.

The plurality of 1-3 connection wires 121c may be positioned on the second organic insulating layer 115b. For example, the plurality of 1-3 connection wires 121c may be disposed to cover a portion of the second organic insulating layer 115b. The plurality of 1-3 connection wires 121c may be electrically connected to the plurality of 1-2 connection wires 121b. For example, the 1-3 connection wire 121c may be electrically connected to the 1-2 connection wire 121b through a contact hole of the second organic insulating layer 115b.

A third insulating layer 115c may be positioned on the plurality of 1-3 connection wires 121c. The third insulating layer 115c may be positioned in a region excluding the bending area BA, but the embodiments of the present disclosure are not limited thereto. For example, the third insulating layer 115c may not be disposed in the entirety or part of the bending area BA, but the embodiments of the present disclosure are not limited thereto.

The third insulating layer 115c may be positioned in the display area AA, the first non-display area NA1, and the second non-display area NA2, but the embodiments of the present disclosure are not limited thereto. For example, a portion of the third insulating layer 115c positioned in the bending area BA may be removed. The third insulating layer 115c may be made of an organic insulating material, but the embodiments of the present disclosure are not limited thereto. For example, the third insulating layer 115c may be made of photoresist, polyimide (PI), or a photoacryl-based material, but the embodiments of the present disclosure are not limited thereto.

The plurality of 1-4 connection wires 121d may be positioned on the third insulating layer 115c. For example, the plurality of 1-4 connection wires 121d may be disposed to cover a portion of the third insulating layer 115c. The plurality of 1-4 connection wires 121d may be electrically connected to the plurality of 1-3 connection wires 121c. For example, the 1-4 connection wire 121d may be electrically connected to the 1-3 connection wire 121c through a contact hole of the third insulating layer 115c.

A fourth organic insulating layer 115d may be disposed on a plurality of 1-4 connection wirings 121d. The fourth organic insulating layer 115d may be disposed in the remaining area except for the bending area BA, but embodiments of the present disclosure are not limited thereto. The fourth organic insulating layer 115d may be disposed in the display area AA, the first non-display area NA1, and the second non-display area NA2, but embodiments of the present disclosure are not limited thereto. For example, a portion of the fourth organic insulating layer 115d positioned in the bending area BA may be removed.

According to the present disclosure, a plurality of second connection wires 122 may be positioned on the second protective layer 113b in the non-display area NA. The plurality of second connection wires 122 may be wires for transmitting a signal, which has been transmitted to the pad portion PAD from the flexible circuit board (or flexible film) CB and the printed circuit board 160 (see FIG. 1), to the pixel driving circuit PD of the display area AA. For example, the plurality of second connection wires 122 may be electrically connected to the plurality of pad electrodes PE to receive a signal from the flexible circuit board (or flexible film) CB and the printed circuit board 160.

A plurality of 2-1 connection wirings (not shown) may be disposed on the second protective layer 113b. A plurality of 2-1 connection wirings (not shown) may extend from the second non-display area NA2 to the bending area BA and the first non-display area NA1. A plurality of 2-1 connection wirings may transmit signals transmitted from the flexible circuit board (or flexible film) CB and the printed circuit board to the pad unit PAD to the pixel driving circuit PD of the display area AA.

A plurality of 2-2 connection wirings (not shown) may be disposed on the first insulating layer 114 and the first organic insulating layer 115a. A plurality of 2-2 connection wirings may be disposed in the second non-display area NA2. The 2-2 connection wiring may be electrically connected to the 2-1 connection wiring through a contact hole of the first stopper layer 114. Accordingly, the signal from the flexible circuit board (or flexible film) CB and the printed circuit board may be transmitted to the 2-1 connection wiring through the 2-2 connection wiring.

A third insulating layer 115c may be disposed on the second organic insulating layer 115b and the 2-3 connection wiring (not shown). Furthermore, a 2-4 connection wiring (not shown) may be disposed on the third insulating layer 115c. The 2-4 connection wiring may be disposed in the second non-display area NA2. The 2-4 connection wiring (not shown) may be electrically connected to the 2-3 connection wiring (not shown) through a contact hole of the third insulating layer 115c. Therefore, the signal from the flexible film FF and the printed circuit board may be transmitted to the 2-1 connection wiring through the 2-4 connection wiring, the 2-3 connection wiring, and the 2-2 connection wiring.

The plurality of first connection wires 121 and the plurality of second connection wires 122 may be formed of a highly flexible conductive material or any one of various conductive materials used in the display area AA.

For example, the second connection wiring 122 in which a part is disposed in the bending area BA may be made of a conductive material having excellent ductility, such as gold (Au), silver (Ag), or aluminum (Al), but embodiments of the present disclosure are not limited thereto.

For another example, the plurality of first connection wires 121 and the plurality of second connection wires 122 may be made of molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto.

The fourth organic insulating layer 115d may be positioned on the plurality of first connection wires 121 and the plurality of second connection wires 122. For example, the fourth organic insulating layer 115d may be disposed to cover the 1-4 connection wire 121d. The fourth organic insulating layer 115d may be positioned in a region excluding the bending area BA, but the embodiments of the present disclosure are not limited thereto. For example, the fourth organic insulating layer 115d may not be disposed in the entirety or part of the bending area BA, but the embodiments of the present disclosure are not limited thereto.

The fourth organic insulating layer 115d may be positioned in the display area AA, the first non-display area NA1, and the second non-display area NA2, but the embodiments of the present disclosure are not limited thereto. A portion of the fourth organic insulating layer 115d in the bending area BA may be removed. The fourth organic insulating layer 115d may be made of an organic insulating material, but the embodiments of the present disclosure are not limited thereto. For example, the fourth organic insulating layer 115d may be made of photoresist, polyimide (PI), or a photoacryl-based material, but the embodiments of the present disclosure are not limited thereto.

Referring to FIG. 8, in the display area AA, the plurality of banks BNK may be positioned on the fourth organic insulating layer 115d. The plurality of banks BNK may respectively overlap the plurality of sub-pixels. One or more micro-LEDs ED that emit light of the same color may be positioned above each of the plurality of banks BNK. For example, one or more micro-LEDs ED of the same type may be disposed on the upper side of each of the plurality of banks BNK.

The bank BNK may be configured with an organic insulating material. However, the embodiments of the present disclosure are not limited thereto. For example, the bank BNK may be made of a photoresist, polyimide (PI), or photo acryl-based material, or the like. However, the embodiments of the present disclosure are not limited thereto. The bank BNK may be made of, for example, a transparent carbon-based mixture. Specifically, the bank BNK may contain carbon black, but is not limited thereto. The bank BNK may also be made of a transparent insulating material. However, the embodiments of the present disclosure are not limited thereto.

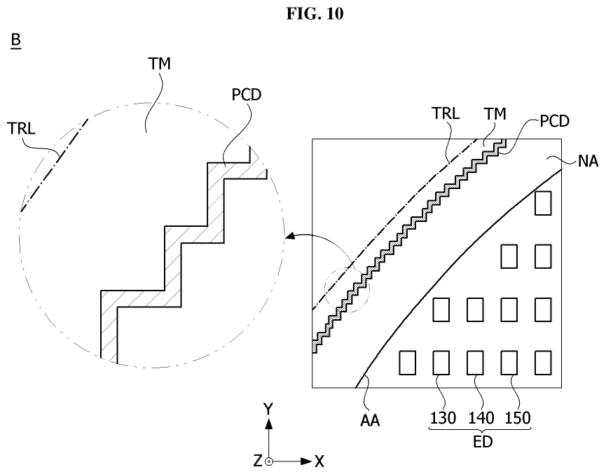

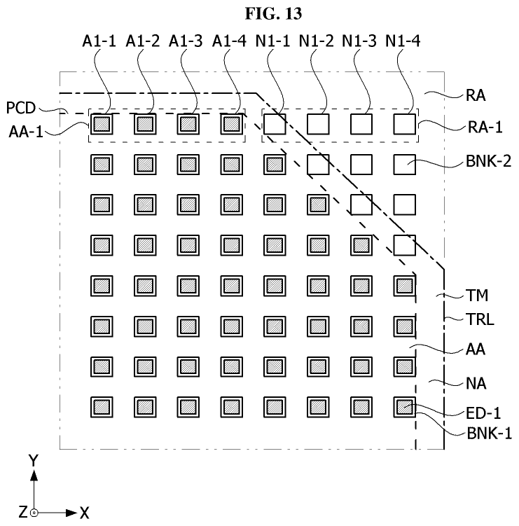

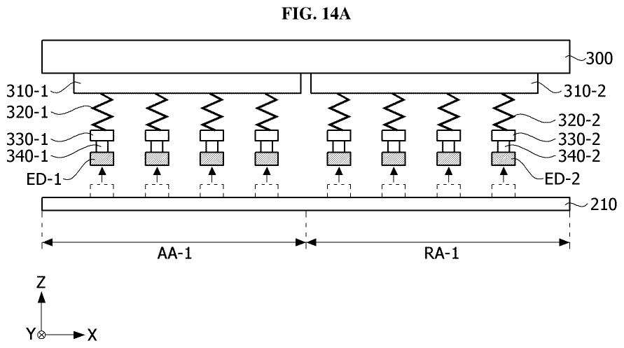

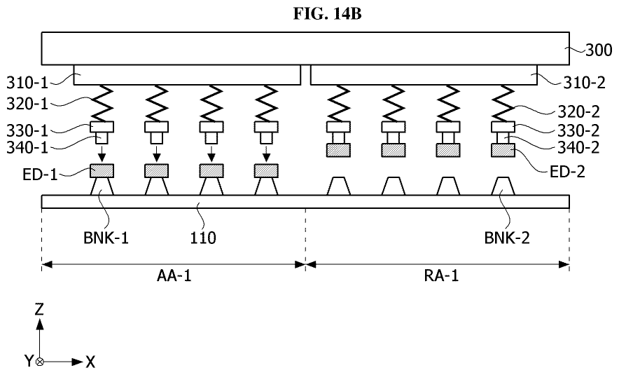

As one example, the bank BNK may include a plurality of banks. For example, the bank BNK may include a first bank BNK-1 of FIG. 13 disposed in the display area AA and a second bank BNK-2 of FIG. 14B disposed in the non-display area NA. The non-display area NA may include a trimming line TRL (TRL of FIG. 10) and a panel crack detection (PCD) line (PCD of FIG. 10), a trimming margin (TM) that is an area between the trimming line TRL and the PCD line, and an outer area of the trimming line (TRL). Here, the second bank BNK-2 may not be formed in the first and second non-display areas NA1 and NA2. However, the present disclosure is not limited thereto. In addition, the light emitting element ED may not be disposed in the non-display area NA including an area between the trimming line TRL and the trimming margin TM and an outer area of the trimming line TRL. Here, the trimming margin TM may be interpreted as a bezel area in a display panel that is a final product.

By selectively controlling the voltage applied to the stamp 310-1 and 310-2 (see FIG. 14A) for transferring light-emitting elements by the transfer control device 300 (see FIG. 14A) in the display area AA and the non-display area NA, it is possible to control the transfer of the light-emitting element ED to the non-display area NA, which is outside the panel. As one example, when the driving voltage is applied to any one of the stamp 310-1 and 310-2, the light-emitting elements may be continuously maintained in contact with the stamp which is applied with the voltage, so that the light-emitting element may not be transferred to the non-display area NA. For example, the voltage application to the stamp 310-1 located in the display area AA is stopped, so that a plurality of light-emitting elements ED-1 in contact with the stamp 310-1 may be separated from the stamp 310-1 and transferred onto the substrate 110. In addition, a plurality of light-emitting elements ED-2 in contact with the stamp 310-2 may be continuously maintained in contact with the stamp 310-2 while the voltage is continuously applied to the stamp 310-2 so that the light-emitting element may not be transferred to the non-display area NA.

A plurality of signal lines TL may be disposed on the fourth organic insulating layer 115d in the display area AA. A plurality of signal lines TL may be disposed in an area between a plurality of banks BNK. For example, a plurality of signal lines TL may be disposed adjacent to any one of a plurality of banks BNK.

The plurality of contact electrodes CCE may be positioned on the fourth organic insulating layer 115d in the display area AA. The plurality of contact electrodes CCE may supply the cathode voltage from the pixel driving circuit PD to the second electrode CE2.

The first electrode CE1 may be positioned on the bank BNK. For example, the first electrode CE1 may extend from an adjacent signal wire TL toward the top of the bank BNK. The first electrode CE1 may be positioned on the top and side surfaces of the bank BNK. For example, the first electrode CE1 may extend from the signal wire TL on the top surface of the fourth organic insulating layer 115d to the side surface of the bank BNK and to the top surface of the bank BNK.

Referring to FIGS. 8 and 9, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto. More or less conductive layers may be included. For example, the first electrode CE1 may be made of one conductive layer.

The first conductive layer CE1a may be positioned on the bank BNK. The second conductive layer CE1b may be positioned on the first conductive layer CE1a. The third conductive layer CE1c may be positioned on the second conductive layer CE1b. The fourth conductive layer CE1d may be positioned on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxide (ITO), but the embodiments of the present disclosure are not limited thereto.

According to the present disclosure, among the plurality of conductive layers constituting the first electrode CE1, some conductive layers with high reflection efficiency may be configured as an alignment key and/or a reflective plate for aligning the micro-LED ED.

For example, the second conductive layer CE1b of the plurality of conductive layers of the first electrode CE1 may include a reflective material. For example, the second conductive layer CE1b may include aluminum (Al). However, embodiments of the present disclosure are not limited thereto. Accordingly, the second conductive layer CE1b may act as the reflective plate. In addition, due to the high reflection efficiency of the second conductive layer CE1b, the second conductive layer CE1b may be easily identified in the manufacturing process, and thus the position of the light-emitting element ED or the transfer position may be aligned with the second conductive layer CE1b.

For example, in order to configure the second conductive layer CE1b as a reflective plate, the third conductive layer CE1c and the fourth conductive layer CE1d covering the second conductive layer CE1b may be partially removed or etched. For example, portions of the third conductive layer CE1c and the fourth conductive layer CE1d positioned on the bank BNK may be removed or etched to expose the top surface of the second conductive layer CE1b. For example, the openings of the third conductive layer CE1c and the fourth conductive layer CE1d may overlap with the exposed top surface of the second conductive layer CE1b. For example, in the third conductive layer CE1c and the fourth conductive layer CE1d, a central portion where the solder pattern SDP is positioned and a border portion (or edge portion) may be left, while the remaining portions may be removed. For example, the border portion (or edge portion) of each of the third conductive layer CE1c formed of titanium (Ti) and the fourth conductive layer CE1d formed of indium tin oxide (ITO) may not be etched. Accordingly, it is possible to prevent another conductive layer of the first electrode CE1 from being corroded by a tetramethylammonium hydroxide (TMAH) solution used in the masking process of the first electrode CE1.

According to the present disclosure, the first conductive layer CE1a and the third conductive layer CE1c may be made of titanium (Ti) or molybdenum (Mo). The second conductive layer CE1b may be made of aluminum (Al). The fourth conductive layer CE1d may include a transparent conductive oxide layer, such as indium tin oxide (ITO) or indium zinc oxide (IZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but embodiments of the present disclosure are not limited thereto.

According to the present disclosure, the signal wire TL, the contact electrode CCE, and the pad electrode PE positioned in the same layer as the first electrode CE1 may be composed of multiple layers of a conductive material, but the embodiments of the present disclosure are not limited thereto. For example, the signal line TL, the contact electrode CCE, and the pad electrode PE may be formed of a multilayer of indium tin oxide (ITO)/titanium (Ti)/aluminum (Al)/titanium (Ti), but embodiments of the present disclosure are not limited thereto. Alternatively, the signal wire TL, the contact electrode CCE, and the pad electrode PE positioned in the same layer as the first electrode CE1 may be configured in a single layer structure of conductive materials.

According to the present disclosure, the solder pattern SDP may be positioned on the first electrode CE1 in each of the plurality of sub-pixels. The solder pattern SDP may bond the micro-LED ED to the first electrode CE1 to electrically connect the first electrode CE1 to the micro-LED ED. The first electrode CE1 and the micro-LED ED may be electrically connected to each other through eutectic bonding using the solder pattern SDP, but is not limited thereto. For example, the first electrode CE1 and the anode electrode 134 of the micro-LED ED may be electrically connected to each other through eutectic bonding using the solder pattern SDP, but the embodiments of the present disclosure are not limited thereto. For example, when the solder pattern SDP is made of indium (In), and the anode electrode 134 of the micro-LED ED is made of gold (Au), the solder pattern SDP and the anode electrode 134 may be bonded by applying heat and pressure during the transfer process of the micro-LED ED. Through eutectic bonding, the micro-LED ED may be bonded to the solder pattern SDP and the first electrode CE1 without a separate adhesive material. For example, the solder pattern SDP may be made of indium (In), tin (Sn), or an alloy thereof, but the embodiments of the present disclosure are not limited thereto. For example, the solder pattern SDP may be a bonding pad or a joining pad, but the embodiments of the present disclosure are not limited thereto.

In addition, referring to FIG. 8, a second insulating layer 116 may be disposed on the fourth organic insulating layer 115d including the first electrode CE1 and a bank BNK. For example, the second insulating layer 116 may be disposed in the entire display area AA and the non-display area NA, but is not limited thereto.

For example, in order to prevent moisture permeation penetrating from the non-display area NA, the second insulating layer 116 may be disposed only in the display area AA. The present disclosure is not limited thereto. For example, the second insulating layer 116 may be disposed on the fourth organic insulating layer 115d in the display area AA, and may be not disposed in the non-display area NA, but is not limited thereto.

In addition, the second insulating layer 116 may be formed of a single layer or multiple layers of silicon oxide (SiOx) or silicon nitride (SiNx), which is an inorganic film material, but embodiments of the present disclosure are not limited thereto.

According to the present disclosure, the second insulating layer 116 serving as the passivation layer may be disposed on a plurality of signal lines TL, a plurality of first electrodes CE1, a plurality of contact electrodes CCE, and a third insulating layer 115c.

For example, the second insulating layer 116 may be positioned in the display area AA, the first non-display area NA1, and the second non-display area NA2. A portion of the second insulating layer 116 positioned in the bending area BA may be removed. In the second non-display area NA2, a portion of the second insulating layer 116 covering the plurality of pad electrodes PE may be removed. Since the second insulating layer 116 is positioned to cover the remaining regions other than the bending area BA and the regions where the plurality of pad electrodes PE and the solder pattern SDP are positioned, penetration of moisture or impurities into the micro-LED ED may be reduced. For example, the second insulating layer 116 may be made of an inorganic insulating material. For example, the second insulating layer 116 may be composed of a single layer or multiple layers of silicon oxide (SiOx) or silicon nitride (SiNx), but the embodiments of the present disclosure are not limited thereto.

In each of the plurality of sub-pixels, the micro-LED ED may be positioned on the solder pattern SDP. Each of the first micro-LED 130, the second micro-LED 140 and the third micro-LED 150 may be disposed in each of the first sub-pixel SP1, the second sub-pixel SP2 and the third sub-pixel SP3, without being limited thereto. The first micro-LED 130 may be positioned in the first sub-pixel SP1. The second micro-LED 140 may be positioned in the second sub-pixel SP2. The third micro-LED 150 may be positioned in the third sub-pixel SP3. Each of the first micro-LED 130, the second micro-LED 140 and the third micro-LED 150 may be embodied as a micro light-emitting element, but is not limited thereto.

The micro-LED ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present disclosure are not limited thereto.

Referring to FIGS. 8 and 9, the first micro-LED 130 may include the anode electrode 134, a first semiconductor layer 131, an active layer 132, a second semiconductor layer 133, the cathode electrode 135, and an encapsulation film 136, but the embodiments of the present disclosure are not limited thereto. For example, the first micro-LED 130 may not include the encapsulation film 136.

A first semiconductor layer 131 may be disposed on the solder pattern SDP. The second semiconductor layer 133 may be disposed on the first semiconductor layer 131, but the embodiments of the present disclosure are not limited thereto.

The anode electrode 134 may be disposed on the solder pattern SDP. The first semiconductor layer 131 may be disposed on the anode electrode 134. The active layer 132 may be disposed on the first semiconductor layer 131. The second semiconductor layer 133 may be disposed on the active layer 132. The cathode electrode 135 may be disposed on the second semiconductor layer 133.

For example, one of the first semiconductor layer 131 and the second semiconductor layer 133 may be implemented as a compound semiconductor of a group III-V or a group II-VI and may be doped with an impurity (or dopant). For example, one of the first semiconductor layer 131 and the second semiconductor layer 133 may be a semiconductor layer doped with an n-type impurity, while the other may be a semiconductor layer doped with a p-type impurity, but the embodiments of the present disclosure are not limited thereto. For example, at least one of the first semiconductor layer 131 and the second semiconductor layer 133 may be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto.

As one example, the first semiconductor layer 131 and the second semiconductor layer 133 may be a nitride semiconductor, without being limited thereto. For example, each of the first semiconductor layer 131 and the second semiconductor layer 133 may be made of a nitride semiconductor including n-type impurities and a nitride semiconductor including p-type impurities. For example, the first semiconductor layer 131 may be made of a nitride semiconductor including p-type impurities, and the second semiconductor layer 133 may be made of a nitride semiconductor including n-type impurities. However, embodiments of the present disclosure are not limited thereto.

The active layer 132 may be positioned between the first semiconductor layer 131 and the second semiconductor layer 133. The active layer 132 may emit light by receiving holes and electrons from the first semiconductor layer 131 and the second semiconductor layer 133. For example, the active layer 132 may be configured in one of a single well structure, a multi-well structure, a single quantum well structure, a multi-quantum well (MQW) structure, a quantum dot structure, and a quantum line structure, but the embodiments of the present disclosure are not limited thereto. For example, the active layer 132 may be made of indium gallium nitride (InGaN) or gallium nitride (GaN), but the embodiments of the present disclosure are not limited thereto.

In another example, the active layer 132 may include a well layer and a multi-quantum well (MQW) structure having a barrier layer having a band gap higher than that of the well layer. For example, the active layer 132 may include InGaN as a well layer and AlGaN layer as a barrier layer, but embodiments of the present disclosure are not limited thereto.

The anode electrode 134 may be disposed between the first semiconductor layer 131 and the solder pattern SDP. For example, the anode electrode 134 may electrically connect the first semiconductor layer 131 to the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material capable of eutectic bonding with the solder pattern SDP. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The cathode electrode 135 may be positioned on the second semiconductor layer 133. For example, the cathode electrode 135 may electrically connect the second semiconductor layer 133 to the second electrode CE2. The cathode voltage outputted from the pixel driving circuit PD may be applied to the second semiconductor layer 133 through the contact electrode CCE, the second electrode CE2, and the cathode electrode 135. The cathode electrode 135 may be formed of a transparent conductive material such that light emitted from the micro-LED ED may be directed toward an upper side of the micro-LED ED, but the embodiments of the present disclosure are not limited thereto. For example, the cathode electrode 135 may be formed of a material such as indium tin oxide (ITO), indium zinc oxide (IZO), or indium gallium zinc oxide (IGZO), but the embodiments of the present disclosure are not limited thereto.

The encapsulation film 136 may be positioned on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135, without being limited thereto. For example, the encapsulation film 136 may not be included in the light-emitting element ED.

For example, the encapsulation film 136 may surround the side surface of the first semiconductor layer 131, the side surface of the active layer 132, and the side surface of the second semiconductor layer 133. For example, the encapsulation film 136 may protect the first semiconductor layer 131, the active layer 132, and the second semiconductor layer 133.

For example, the encapsulation film 136 may be disposed on at least a portion of the anode electrode 134 and the cathode electrode 135, for example, on the edge portion (or edge portion or one side) of the anode electrode 134 and the edge portion (or edge portion or one side) of the cathode electrode 135. For example, the encapsulation film 136 may surround an edge portion or a border portion or one side of the anode electrode 134 and an edge portion or a border portion or one side of the cathode electrode 135. At least a portion of the anode electrode 134 may be exposed from the encapsulation film 136 to connect the anode electrode 134 and the solder pattern SDP. For example, at least a portion of the cathode electrode 135 may be exposed from the encapsulation film 136 to connect the cathode electrode 135 and the second electrode CE2. For example, the encapsulation film 136 may be formed of an insulating material such as silicon nitride (SiNx) or silicon oxide (SiOx), but embodiments of the present disclosure are not limited thereto.

In another example, the encapsulation film 136 may have a structure in which a reflective material is dispersed in a resin layer, but embodiments of the present disclosure are not limited thereto. For example, the encapsulation film 136 may be manufactured as a reflector having various structures, but embodiments of the present disclosure are not limited thereto. Light emitted from the active layer 132 by the encapsulation film 136 may be reflected upward to improve light extraction efficiency. For example, the encapsulation film 136 may be a reflective layer, but embodiments of the present disclosure are not limited thereto.

Although the light emitting element ED has been described as a vertical type structure according to the present disclosure, embodiments of the present disclosure are not limited thereto. For example, the light emitting element ED may have a lateral STA structure or a flip chip STA structure.

Although the first light emitting device 130 has been described with reference to FIG. 9, the second light emitting device 140 and the third light emitting device 150 may have substantially the same or similar to structure as the first light emitting device 130. For example, the second light emitting device 140 and the third light emitting device 150 may be substantially the same as the first semiconductor layer 131, the active layer 132, the second semiconductor layer 133, the anode electrode 134, the cathode electrode 135, and the encapsulation film 136.

For example, the first semiconductor layer, the active layer, the second semiconductor layer, the anode electrode, the cathode electrode, and the encapsulation film of each of the second light emitting device 140 and the third light emitting device 150 may be substantially the same as or similar to the first semiconductor layer 131, the active layer 132, the second semiconductor layer 133, the anode electrode 134, the cathode electrode 135, and the encapsulation film 136 of the first light emitting device 130, respectively.

The optical insulating layer may include a plurality of optical layers. For example, the optical insulating layer 117 may include a first optical layer 117a, a second optical layer 117b, and a third optical layer 117c, without being limited thereto. More or less optical layers may be included.

According to the present disclosure, a first optical layer 117a may be positioned on the second insulating layer 116 to surround the plurality of micro-LEDs ED in the display area AA. For example, the first optical layer 117a may be positioned to cover the plurality of micro-LEDs ED and the bank BNK in regions of the plurality of sub-pixels. For example, the first optical layer 117a may cover the bank BNK, a portion of the second insulating layer 116 and the spaces between adjacent ones of the plurality of micro-LEDs ED. The first optical layer 117a may be positioned between the plurality of banks BNK and between the plurality of micro-LEDs ED included in one pixel PX, or may cover those spaces. For example, the first optical layer 117a may extend in a first direction X and may be separated in a second direction Y For example, the first optical layer 117a may be positioned between the second insulating layer 116 and the second electrode CE2 to surround the side portions of the micro-LED ED and the bank BNK, but the embodiments of the present disclosure are not limited thereto. For example, the first optical layer 117a may be a diffusion layer, a sidewall diffusion layer, or the like, but the embodiments of the present disclosure are not limited thereto.

The first optical layer 117a may be formed of an organic insulating material in which fine particles are dispersed, but the embodiments of the present disclosure are not limited thereto. For example, the first optical layer 117a may be made of siloxane in which fine metal particles such as titanium dioxide (TiO₂) particles are dispersed, but the embodiments of the present disclosure are not limited thereto. Light from the plurality of micro-LEDs ED may be scattered by the fine particles dispersed in the first optical layer 117a and emitted to the outside of the display device 1000. Accordingly, the first optical layer 117a may improve the light extraction efficiency of the light emitted from the plurality of micro-LEDs ED.

For example, the first optical layer 117a may be positioned in each of the plurality of pixels PX, or may be commonly positioned in some of the pixels PX arranged in the same row, but the embodiments of the present disclosure are not limited thereto. For example, the first optical layer 117a may be positioned in each of the plurality of pixels PX, or a single first optical layer 117a may be shared by the plurality of pixels PX. In another example, each of the plurality of sub-pixels may separately include the first optical layer 117a, but the embodiments of the present disclosure are not limited thereto.

According to the present disclosure, the second optical layer 117b may be disposed on the second insulating layer 116 in the display area AA. For example, the second optical layer 117b may be disposed to surround the first optical layer 117a. For example, the second optical layer 117b may be in contact with the side surface of the first optical layer 117a. For example, the second optical layer 117b may be disposed in an area between a plurality of pixels PX. However, embodiments of the present disclosure are not limited thereto, for example, the second optical layer 117b may be a diffusion layer, a diffusion layer window, a window diffusion layer, or the like, but embodiments of the present disclosure are not limited thereto.

The second optical layer 117b may be formed of an organic insulating material, but embodiments of the present disclosure are not limited thereto. The second optical layer 117b may be formed of the same material as the first optical layer 117a, but embodiments of the present disclosure are not limited thereto. For example, the second optical layer 117b may be composed of the different material from the first optical layer 117a. For example, the first optical layer 117a may include fine particles, and the second optical layer 117b may not include fine particles. For example, the second optical layer 117b may be formed of siloxane, but embodiments of the present disclosure are not limited thereto.

For example, the thickness of the first optical layer 117a may be less than that of the second optical layer 117b, but embodiments of the present disclosure are not limited thereto. Accordingly, when viewed in a plan view, the region in which the first optical layer 117a is disposed may include a concave portion recessed inwardly from the upper surface of the second optical layer 117b.

According to the present disclosure, the second electrode CE2 may be disposed on the first optical layer 117a and the second optical layer 117b. For example, the second electrode CE2 may be electrically connected to a plurality of contact electrodes CCE through a contact hole of the second optical layer 117b. For example, the second electrode CE2 may be disposed on a plurality of light emitting elements ED. For example, the second electrode CE2 may include a transparent conductive oxide such as indium tin oxide (ITO) or indium zinc oxide (IZO), but embodiments of the present disclosure are not limited thereto. For example, the second electrode CE2 may be disposed to be in contact with the cathode electrode 135. For example, the second electrode CE2 may overlap the first optical layer 117a. For example, the outer plane of the first optical layer 117a may be covered by the second electrode CE2. The second electrode CE2 may continuously extend in the first direction X of the substrate 110.

Accordingly, the substrate 110 may be commonly connected to a plurality of pixels PX arranged in the first direction X. For example, the second electrode CE2 may be commonly connected to a plurality of pixels PX.

According to the present disclosure, the second electrode CE2 may continuously extend on the first optical layer 117a, the second optical layer 117b, and the plurality of light emitting elements ED. The region in which the first optical layer 117a is disposed may include a concave portion recessed inwardly from the upper surface of the second optical layer 117b. Accordingly, since the first portion of the second electrode CE2 disposed on the first optical layer 117a is disposed along the concave portion, the first portion may be disposed at a lower position than the second portion of the second electrode CE2 disposed on the second optical layer 117b.

In addition, the third insulating layer (not shown) may be disposed on the second electrode CE2 and the first optical layer 117a. For example, the third insulating layer (not shown) may be disposed in the entire display area AA and the non-display area NA, but is not limited thereto. For example, the third insulating layer may be formed of a single layer or multiple layers of silicon oxide (SiOx) or silicon nitride (SiNx), which is an inorganic film material, but embodiments of the present disclosure are not limited thereto.

For example, in order to prevent moisture permeation from penetrating from the non-display area NA, the third insulating layer (not shown) may be disposed in the display area AA but not the non-display area NA. However, the present disclosure is not limited thereto. For example, the third insulating layer (not shown) may be disposed on the second electrode CE2 and the first optical layer 117a in the display area AA, but is not limited thereto.

The third optical layer 117c may be disposed on the second electrode CE2. The third optical layer 117c may be disposed to overlap a plurality of light emitting elements ED and the first optical layer 117a. Since the third optical layer 117c is disposed on the second electrode CE2 and a plurality of light emitting elements ED, a stain (Mura) that may occur in some of a plurality of light emitting elements ED may be improved. For example, when a plurality of light emitting elements ED are transferred onto the substrate 110 of the display device 1000, a region in which a gap between adjacent ones of a plurality of light emitting elements ED is not uniform due to a process variation or the like may occur. When the spacing between adjacent ones of the plurality of light emitting elements ED is non-uniform, the light emitting area of each of the plurality of light emitting elements ED may be non-uniformly disposed, and thus a stain (Mura) may be visually recognized by the user.

Accordingly, since the third optical layer 117c configured to uniformly diffuse light on the plurality of light emitting elements ED is configured, light emitted from some light emitting elements ED may be reduced from being visually recognized like a stain.

Therefore, since the light emitted from the plurality of light emitting elements ED is evenly diffused by the third optical layer 117c and extracted to the outside of the display device 1000, the luminance uniformity of the display device 1000 may be improved.

The third optical layer 117c may be formed of an organic insulating material in which fine particles are dispersed, but embodiments of the present disclosure are not limited thereto. For example, the third optical layer 117c may be formed of siloxane in which fine metal particles such as titanium dioxide (TiO₂) particles are dispersed, but embodiments of the present disclosure are not limited thereto. For example, the third optical layer 117c may be formed of the same material as the first optical layer 117a, but embodiments of the present disclosure are not limited thereto. The third optical layer 117c may be composed of the different material from the first optical layer 117a, but the embodiments of the present disclosure are not limited thereto. For example, the third optical layer 117c may be a diffusion layer, an upper diffusion layer, or the like, but embodiments of the present disclosure are not limited thereto.

According to the present disclosure, light from a plurality of light emitting elements ED may be scattered by fine particles dispersed in the third optical layer 117c and emitted to the outside of the display device 1000. The third optical layer 117c may evenly mix light emitted from a plurality of light emitting elements ED to further improve luminance uniformity of the display device 1000. In addition, light extraction efficiency of the display device 1000 may be improved by light scattered from a plurality of fine particles, and thus the display device 1000 may be driven at a low power.

In the display area AA, a black matrix BM may be disposed on the second electrode CE2, the first optical layer 117a, the second optical layer 117b, the third optical layer 117c, and the third insulating layer (not shown). For example, the black matrix BM may be configured to cover the second electrode CE2, the first optical layer 117a, the second optical layer 117b, the third optical layer 117c, and the third insulating layer (not shown) in the display area AA. For example, the black matrix BM may fill a contact hole of the second optical layer 117b. Since the black matrix BM is configured to cover the display area AA, color mixture and reflection of external light of a plurality of sub-pixels may be reduced or prevented. For example, since the black matrix BM is disposed within a contact hole in which the second electrode CE2 is connected with the contact electrode CCE, light leakage between a plurality of neighboring sub-pixels may be prevented or reduced.

For example, the black matrix BM may be formed of an opaque material, but embodiments of the present disclosure are not limited thereto. For example, the black matrix BM may be an organic insulating material to which a black pigment or a black dye is added, but embodiments of the present disclosure are not limited thereto.

In the display area AA, a cover layer 119 of FIG. 8 may be disposed on the black matrix BM. For example, the cover layer 119 may be configured to cover the components under the cover layer 119. The cover layer 119 may protect an element under the third insulating layer (not shown), for example, the cover layer 119 may be formed of an organic insulating material, but embodiments of the present disclosure are not limited thereto. For example, the cover layer 119 may be formed of a photo resist, polyimide (PI), a photo acryl-based material, or the like, but embodiments of the present disclosure are not limited thereto. For example, the cover layer 119 may be an overcoating layer, an insulating layer, or the like, but embodiments of the present disclosure are not limited thereto.

As shown in FIG. 8, the polarizing layer 293 may be disposed on the cover layer 119 via the first adhesive layer 291. For example, the polarizing layer 293 may be configured to cover the first adhesive layer 291, and the first adhesive layer 291 may be configured to cover the cover layer 119. The cover member 120 may be disposed on the polarizing layer 293 via the second adhesive layer 295. For example, the first adhesive layer 291 and the second adhesive layer 295 may include an optically clear adhesive (OCA), an optically clear resin (OCR), a pressure sensitive adhesive (PSA) or the like, but embodiments of the present disclosure are not limited thereto.

According to the present disclosure, a plurality of pad electrodes PE may be disposed on the fourth organic insulating layer 115d in the second non-display area NA2. For example, at least portions of a plurality of pad electrodes PE may be exposed from the second insulating layer 116. For example, a plurality of pad electrodes PE may be electrically connected to the 2-4th connection wiring 122d through a contact hole of the fourth organic insulating layer 115d.

An adhesive layer (not shown) may be disposed on a plurality of pad electrodes PE. For example, the adhesive layer may be configured to cover the plurality of pad electrodes PE. The adhesive layer may be an adhesive layer in which conductive balls are dispersed in an insulating material, but embodiments of the present disclosure are not limited thereto. When heat or pressure is applied to the adhesive layer, the conductive balls may be electrically connected to each other in a portion where heat or pressure is applied to have conductive characteristics. An adhesive layer may be disposed between a plurality of pad electrodes PE and a flexible circuit board (or a flexible film) CB to attach or bond a flexible circuit board (or a flexible film) CB to a plurality of pad electrodes PE. For example, the adhesive layer may be an anisotropic conductive film (ACF), but embodiments of the present disclosure are not limited thereto.

A flexible circuit board (or a flexible film) CB (see FIG. 1) may be disposed on the adhesive layer. For example, the flexible circuit board (or a flexible film) CB (see FIG. 1) may be disposed to cover the adhesive layer. The flexible circuit board (or a flexible film) CB may be electrically connected to a plurality of pad electrodes PE through an adhesive layer. Thus, the signals output from the flexible circuit board (or flexible film) CB and the printed circuit board may be transmitted to the pixel driving circuit PD of the display area AA through a plurality of pad electrodes PE, a 2-4 connection wiring 122d, a 2-3 connection wiring 122c, a 2-2 connection wiring 122b, and a 2-1 connection wiring 122a.

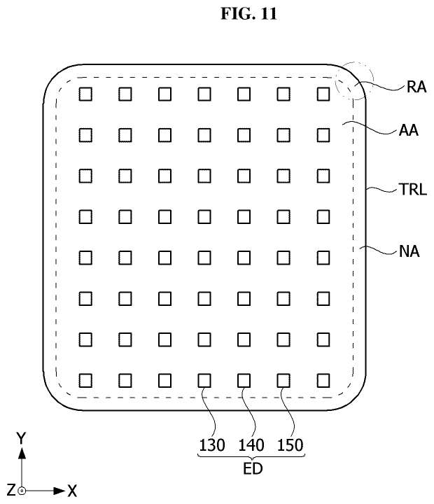

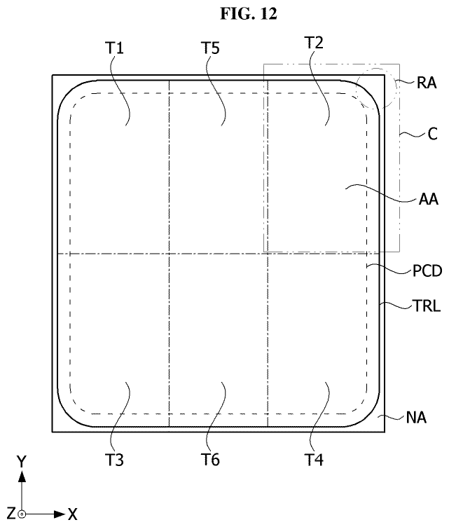

FIG. 10 is a plan view of part B of FIG. 3, and is an enlarged plan view illustrating a part of a transfer region and a non-reflection region of a display device according to an exemplary embodiment of the present disclosure. FIG. 11 is a plan view of the display device according to an exemplary embodiment of the present disclosure. FIG. 12 is a plan view showing transfer regions of the display device according to an exemplary embodiment of the present disclosure. FIG. 13 is an enlarged plan view of portion ‘C’ in FIG. 12 according to an exemplary embodiment of the present disclosure.

Referring to FIG. 10 to 13, the display device according to one exemplary embodiment of the present disclosure may include a display region AA and a non-display region NA adjacent to the display region AA. For example, the non-display region NA may surround the display region AA.

The non-display region NA may include a first non-display region (see NA1 of FIG. 2), a bending region (see BA of FIG. 2), and a second non-display region (see NA2 of FIG. 2). The bending region may be disposed between the first non-display region and the second non-display region. For example, the display region AA may be configured in various shapes depending on the design of the display device (see 1000 of FIG. 2). For example, the display region AA may be configured in a rectangular shape whose four corners are formed in a round shape, but the embodiments of the present disclosure are not limited thereto. In another example, the display region AA may be configured in a rectangular shape whose four corners are formed in a right-angled shape, a circular shape, or the like, but the embodiments of the present disclosure are not limited thereto. As the bending region (see BA of FIG. 2) is in a bent state, the second non-display region (see NA2 of FIG. 2) may be positioned on the rear surface of the display region AA.

Here, the first non-display region (see NA1 of FIG. 2) may be defined as a form surrounding the display region AA. For example, the first non-display region (see NA1 of FIG. 2) may surround at least a portion of the display region AA. The bending region may be defined in the non-display region NA extending from the display region AA, and may be a bendable region. Further, the second non-display region may include a non-display region extending from the bending region BA and surrounding the display region where a pad portion PAD is located. The first and second non-display regions NA1 and NA2 may also be collectively described as the non-display region NA. The non-display region NA may be disposed outside of the display region AA.

Further, a plurality of light-emitting elements ED are disposed in the display region AA, but are not disposed in the non-non-display region NA. For example, the light-emitting elements ED are not disposed in a trimming line TRL included in the non-display region NA, a trimming margin TM which is a region between the trimming line TRL and a panel crack detection (PCD) line, and a region between a PCD region and the display region AA. For example, the plurality of light-emitting elements ED may be disposed in the display region AA located inside the trimming line TRL (e.g., at a first side of the trimming line TRL) which is a curved boundary line of a heterogeneous portion RA, and are not disposed in the non-display region NA inside the trimming line TRL which is the curved boundary line. Further, the plurality of light-emitting elements ED are also not disposed outside the trimming line TRL (e.g., at a second side of the trimming line TRL) which is the curved boundary line. Thus, the non-display region NA outside of the trimming line TRL lacks any light-emitting elements. For example, since the outside of the trimming line TRL which is the curved boundary line is included at an end of a bezel and does not remain in a display panel which is a final product, the light-emitting elements may be disposed outside the trimming line TRL. Here, the curved boundary line may also be described as a heterogeneous portion.

By selectively controlling the voltage applied to the stamp 310-1 and 310-2, it is possible to control the transfer of the light-emitting element ED. When light-emitting elements ED-1 and ED-2 are transferred onto a substrate 110 using stamps (310-1 and 310-2 in FIG. 14A) for transferring light-emitting elements, since a voltage applied to the stamps 310-1 and 310-2 which transfer the light-emitting elements is individually selected and controlled by transmitting transfer coordinates (A1-1 to A1-4 in FIG. 13) of the light-emitting elements of the display region AA and non-transfer coordinates (N1-1 to N1-4 in FIG. 13) of the light-emitting elements of the non-display region NA to a transfer control device 300 which controls the stamps 310-1 and 310-2 for transferring light-emitting elements, transfer control of the light-emitting elements in the display region AA and the non-display region NA may be possible.

Here, the transfer coordinates may mean coordinate values which specify a position (location) of the display region AA inside the trimming line TRL where light-emitting elements will be disposed in the display region AA. The non-transfer coordinates include coordinate values which specify positions (locations) of the trimming line TRL outside the display region AA and the outside of the trimming line TRL where light-emitting elements will not be disposed.

The transfer coordinates and the non-transfer coordinates may be generated through a comparison result between map data which specifies the positions where each light-emitting element will be transferred and trimming line map data which sets the trimming line TRL.

As one example, the transfer coordinate map data and non-transfer coordinate map data may be transmitted to a memory unit (e.g., memory), and a data comparison circuit may be configured to compare and analyze the transfer coordinate map data and the non-transfer coordinate map data and determine the transfer coordinate data and non-transfer coordinate data, but is not limited thereto.

Here, the map data and the trimming line map data which specify transfer and non-transfer positions may be transmitted to memory (not shown) in the transfer control device 300 in FIG. 14A. Further, in a data comparison unit (data comparison circuit) (not shown) provided in the transfer control device 300, the transfer coordinates of the light-emitting elements that is transferred to the display region inside the heterogeneous portion RA including the trimming line including the curved boundary line and the non-transfer coordinates of the light-emitting elements that is not transferred to the non-display region inside the heterogeneous portion RA are determined by comparing the map data and the trimming line map data which specify the transfer positions of the light-emitting elements in the display region and non-transfer positions where light-emitting elements are not to be transferred in the non-display region.

As one example, the transfer control device 300 may be configured to control the transfer of the light-emitting element ED to the non-display area NA by selectively applying a driving voltage to the stamp 310-1 and 310-2 (see FIG. 14A) for transferring light-emitting elements, but is not limited thereto.

As the transfer control device 300 transfers the light-emitting elements ED to the display region AA and does not transfer the light-emitting elements ED to the non-display region NA by selectively applying a driving voltage according to transfer coordinate and non-transfer coordinate data determined through the data comparison unit to the stamps 310-1 and 310-2 for transferring light-emitting elements, interference of light-emitting element chips inside and outside the trimming line TRL which is the non-display region NA may be prevented during a trimming process using laser.

Further, in the heterogeneous portion RA including the trimming line TRL which is the curved boundary line, since the plurality of light-emitting elements ED are transferred to the display region AA and need not to be transferred to the non-display region NA and thus a problem in that the plurality of light-emitting elements ED are unnecessarily used may be solved, manufacturing costs and the reliability of the product may be enhanced.

Referring to FIG. 10, due to the selective driving of the stamps (310-1 and 310-2 in FIG. 14A) for transferring light-emitting elements, the plurality of light-emitting elements ED are transferred to and disposed in the display region AA, but not disposed in the trimming line TRL and a trimming margin line TML located in the non-display region NA, and the PCD region. Accordingly, it is possible to prevent a problem of interference caused by the plurality of light-emitting elements ED unnecessarily transferred to and disposed in the non-display region NA while trimming using laser.

Referring to FIG. 11, the plurality of light-emitting elements ED are disposed in the display region AA, but no light-emitting elements ED are present in the non-display region NA surrounding the display region AA. For example, the transfer control device 300 may control the plurality of light-emitting elements ED to be transferred to the display region AA, without being transferred to the non-display region NA. Specifically, since the coordinates (for example, N1-1 to N1-4 in FIG. 13) of the points located in a round region RA of the non-display region NA, for example, inside and outside the trimming line are transmitted to the transfer control device (300 in FIG. 14A), the transfer control device 300 may control the transfer of the stamps for the coordinate data of the non-display region so that the light-emitting elements ED are not transferred to the non-display region NA, specifically, the round region RA.

Referring to FIG. 12, the plurality of light-emitting elements ED disposed in the display region AA and forming pixels PXL may be micro-sized inorganic light-emitting elements. The plurality of light-emitting elements may be grown on a silicon wafer and then attached to the display panel through a transfer process.

The transfer process of the plurality of light-emitting elements ED may be performed for each previously partitioned region. For example, in FIG. 12, an example in which the display region AA is partitioned into six transfer regions T1 to T6 is described, but the sizes or number of divided transfer regions are not limited thereto. The transfer process may be performed sequentially or simultaneously in the first transfer region T1 to the sixth transfer region T6. As one example, the light-emitting elements of different colors may be sequentially transferred to each of the first to sixth transfer regions T1 to T6. For example, a blue light-emitting element (not shown), a green light-emitting element (not shown), and a red light-emitting element (not shown) may be sequentially transferred to each of the first to sixth transfer regions T1 to T6. However, the present disclosure is not limited thereto.

The first to fourth transfer regions T1 to T4 may include the heterogeneous portion RA of the non-display region NA and the display region AA. For example, when the plurality of light-emitting elements ED are transferred using the stamps (310-1 and 310-2 in FIG. 14A), the transfer process may be performed through a heterogeneous transfer process.

Specifically, before performing the heterogeneous transfer using the stamps (310-1 and 310-2 in FIG. 14A), the coordinates located in the transfer region and the non-transfer region are measured and the measured coordinates are transmitted to the transfer control device 300.

As the transfer control device 300 determines whether to apply the voltage to the stamps according to the transmitted coordinate data and selectively drives the stamps 310-1 and 310-2 located in the first to fourth transfer regions T1 to T4 to perform the transfer, the heterogeneous transfer by the stamps 310-1 and 310-2 is performed.

As one example, among the first to fourth transfer regions T1 to T4, the driving voltage may be selectively applied to the stamp 310-1 located in the display region AA and the stamp 310-2 located in the non-display region NA. For example, among the first to fourth transfer regions T1 to T4, the driving voltage may be applied to the stamp located in the non-display region NA, the plurality of light-emitting elements may be not transferred onto the substrate. For example, among the first to fourth transfer regions T1 to T4, the driving voltage may be not applied to the stamp located in the display region AA, the plurality of light-emitting elements may be transferred onto the substrate.

For example, among the first to fourth transfer regions T1 to T4, a plurality of light-emitting elements (ED-1 in FIG. 14A) are transferred to the display region AA, and the plurality of light-emitting elements ED-1 are not transferred to the heterogeneous portion RA of the non-display region NA which is the curved boundary line. Thus, the heterogeneous portion RA lacks any light-emitting elements. For example, as the voltage is blocked from being applied to the stamp 310-1 located in the display region AA of the first to fourth transfer regions T1 to T4 to turn off static electricity maintained in the stamp 310-1, the plurality of light-emitting elements ED-1 are separated from the stamp 310-1 and normally transferred onto the substrate 110. Further, when the voltage is continuously applied to the stamp 310-2 located in the non-display region NA of the first to fourth transfer regions T1 to T4, as the static electricity is continuously maintained in an on state in the stamp 310-2, the plurality of light-emitting elements continuously adhere to the stamp 310-2 and thus the plurality of light-emitting elements ED-2 are not transferred onto the substrate (110 in FIG. 14B).

Accordingly, as the heterogeneous transfer is performed in the first to fourth transfer regions T1 to T4, the plurality of light-emitting elements ED may be selectively transferred to the display region AA and not be transferred to the non-display region NA.

Further, when the stamp 310-1 is located in the fifth and sixth transfer regions T5 and T6 to transfer the light-emitting elements, as the transfer control device 300 blocks the voltage from being applied to the stamp 310-1 located in the display region AA according to the coordinate data of the fifth and sixth transfer regions T5 and T6 to turn off the static electricity, the plurality of light-emitting elements ED picked up on the stamp 310-1 are transferred onto and disposed on the bank BNK on the substrate 110.

Accordingly, as the plurality of light-emitting elements ED selectively control transfer portions 330-1 and 330-2 of the stamps 310-1 and 310-2 by the transfer control device 300, the plurality of light-emitting elements ED may be selectively transferred only to the transfer region.

FIG. 13 is an enlarged plan view of portion C in FIG. 12, a first display region AA-1 of the display region AA and a first heterogeneous portion RA-1 which is a first non-display region NA-1 of the non-display region NA will be described as examples.

Referring to FIG. 13, the plurality of light-emitting elements ED-1 are disposed in the display region AA, and the plurality of light-emitting elements ED-1 are not disposed in the non-display region NA surrounding the display region AA. Thus, the non-display region NA lacks any light-emitting elements. Specifically, the non-display region NA includes the trimming line TRL. The plurality of light-emitting elements are not disposed in the heterogeneous portion RA of the non-display region NA. Thus, the heterogeneous portion RA of the non-display region NA lacks any light-emitting elements. Further, a PCD line PCD may be disposed in the non-display region NA to be located between the trimming line TRL and the display region AA.

For example, the transfer coordinates of the display region may be set. For example, the plurality of light-emitting elements may be transferred to the transfer coordinates in the display region. In addition, the position coordinates may be set for each transfer region located in the display region AA, for example, each region where the light-emitting elements are transferred and disposed. For example, the transfer position coordinates of the light-emitting elements in the first display region AA-1 of the display region AA overlapping the second transfer region T2 may include a first transfer coordinate A1-1, a second transfer coordinate A1-2, a third transfer coordinate A1-3, and a fourth transfer coordinate A1-4. However, the present disclosure is not limited thereto. Here, the first transfer coordinate A1-1 may mean a coordinate at a position in a first row and a first column of the display region AA. Further, the second transfer coordinate A1-2 may mean a coordinate at a position in the first row and a second column of the display region AA. The third transfer coordinate A1-3 may mean a coordinate at a position in the first row and a third column of the display region AA. The fourth transfer coordinate A1-4 may mean a coordinate at a position in the first row and a fourth column of the display region AA. However, the present disclosure is not limited thereto.

The map data of the transfer coordinates set in this way may be input and stored in the memory unit provided in the transfer control device (300 in FIG. 14A).

For example, the non-transfer coordinates of the non-display region NA may be set. For example, the plurality of light-emitting elements may be not transferred to the non-transfer coordinates in the non-display region. Meanwhile, the position coordinates may be set for each non-transfer region located in the non-display region NA, for example, each region where the light-emitting elements are not transmitted. For example, the light-emitting element transfer position coordinates in the first non-display region NA-1 of the non-display region NA overlapping the second transfer region T2 may include a first non-transfer coordinate N1-1, a second non-transfer coordinate N1-2, a third non-transfer coordinate N1-3, and a fourth non-transfer coordinate N1-4. However, the present disclosure is not limited thereto. Here, the first non-transfer coordinate N1-1 may mean a coordinate at a position in a first row and a first column of the non-display region NA. Further, the second non-transfer coordinates N1-2 may mean a coordinate at a position in the first row and a second column of the non-display region NA. In addition, the third non-transfer coordinates N1-3 may mean a coordinate at a position in the first row and a third column of the non-display region NA. In addition, the fourth non-transfer coordinate N1-4 may mean a coordinate at a position in the first row and a fourth column of the non-display region NA. However, the present disclosure is not limited thereto.

The map data of the non-transfer coordinates set in this way may also be input and stored in the memory unit provided in the transfer control device (300 in FIG. 14A).

For example, the first to fourth transfer coordinates A1-1 to A1-4 of the first display region AA-1 and the first to fourth non-transfer coordinates N1-1 to N1-4 of the first heterogeneous portion RA-1 may be input into the transfer control device (300 in FIG. 14A). Further, data on the light-emitting element transfer coordinates located in the remaining display region AA and the non-transfer coordinates located in the non-display region NA may also be stored in the transfer control device (300 in FIG. 14A).

In addition, the position coordinate map data of the trimming line TRL outside the display region AA, for example, the trimming line TRL located in the heterogeneous portion RA including the curved boundary line may be input into the transfer control device 300 and may be input into and stored in the memory unit.

A bank BNK-1 may be disposed for each of the transfer coordinates in the display region AA, and a bank BNK-2 may be disposed for each of the non-transfer coordinates in the non-display region NA. However, the present disclosure is not limited thereto. For example, the bank BNK-2 may not be disposed for each of the non-transfer coordinates in the non-display region NA.

As described below, after comparing the data of the transfer coordinates of the light-emitting elements in the display region AA input and stored in the memory unit in the transfer control device 300, the data of the non-transfer coordinates in the non-display region NA, and the map data of the trimming line TRL in the data comparison unit in the transfer control device 300, the transfer control device 300 selectively applies or does not apply the voltage to the stamps 310-1 and 310-2 for transferring light-emitting elements depending on the compared data. Specifically, the transfer is performed while turning off the voltage on the stamp 310-1 in the display region AA where the transfer of the light-emitting element is required, and maintaining the voltage on the stamp 310-2 inside the trimming line TRL which is the curved boundary line in the heterogeneous portion RA located in the non-display region NA where the transfer of the light-emitting element is not required.

As one example, the voltage may be applied to the stamp on the non-transfer coordinates in the non-display region, and the voltage may be not applied to the stamp located on the transfer coordinates in the display region. In this way, the plurality of light-emitting elements may be transferred to the transfer coordinates in the display region, and the plurality of light-emitting elements may be not transferred to the non-transfer coordinates in the non-display region, but is not limited thereto.

Accordingly, through selective driving of the stamps 310-1 and 310-2, the plurality of light-emitting elements ED-1 are transferred to the display region AA where the transfer of the light-emitting element is required, and the plurality of light-emitting elements ED-2 are not transferred inside the trimming line TRL which is the curved boundary line of the heterogeneous portion RA in the non-display region NA where the transfer of the light-emitting element is not required.

Specifically, the plurality of light-emitting elements ED-1 are transferred for each region, for example, for each of the first to sixth transfer regions T1 to T6. The transfer coordinate and non-transfer coordinate map data of the plurality of light-emitting elements ED-1 and ED-2 may be different for each of the first to sixth transfer regions T1 to T6.

Further, the transfer control device 300 may selectively apply or not apply the voltage to the stamps 310-1 and 310-2, and selectively control whether to apply the voltage or not according to the transfer coordinates and non-transfer coordinates determined after comparison through the data comparison unit in the transfer control device 300 to selectively control the voltage which separates or fixes the light-emitting elements picked up through element transfer portions 330-1 and 330-2 connected to the stamp 310-1 and 310-2 from the stamp. However, the present disclosure is not limited thereto.

FIG. 14A is a cross-sectional view showing a picked-up state of a light-emitting element in the display device according to the exemplary embodiment of the present disclosure. FIG. 14B is a cross-sectional view showing a selective transfer state of the light-emitting element in the display device according to the exemplary embodiment of the present disclosure.

Referring to FIGS. 14A and 14B, a plurality of stamps 310-1 and 310-2 are mounted on the transfer control device 300. However, the present disclosure is not limited thereto.

A plurality of first elastic portions 320-1 which move up and down are provided on a first stamp 310-1, and a first element transfer portion 330-1 may be provided at a lower end of each first elastic portion 320-1. A plurality of first adhesive portions 340-1 capable of picking up the light-emitting elements ED-1 may be provided at lower ends of the first element transfer portions 330-1. However, the present disclosure is not limited thereto.

Further, a plurality of second elastic portions 320-2 which move up and down are provided on a second stamp 310-2, and a second element transfer portion 330-2 may be provided at a lower end of each second elastic portion 320-2. In addition, a plurality of second adhesive portions 340-2 capable of picking up the light-emitting elements ED-2 may be provided at lowers end of the second element transfer portions 330-2.

The first and second stamps 310-1 and 310-2 may be selectively and individually driven by the control of the transfer control device 300.

Referring to FIG. 14A, the transfer control device 300 primarily picks up the plurality of light-emitting elements ED-1 and ED-2 provided on a wafer substrate 210 through the first and second element transfer portions 330-1 and 330-2 while applying the voltage to the first stamp 310-1 and the second stamp 310-2.

For example, when applying the voltage to the first stamp 310-1, the first stamp 310-1 primarily picks up the plurality of light-emitting elements ED-1 provided on a wafer substrate 210, and when applying the voltage to the second stamp 310-2, the second stamp 310-2 primarily picks up the plurality of light-emitting elements ED-2 provided on a wafer substrate 210.

For example, the transfer control device 300 may perform a process of transferring the light-emitting elements to the first to sixth transfer regions T1 to T6.

For example, an example in which the plurality of light-emitting elements ED-1 are transferred to the second transfer region T2 will be described.

First, as shown in FIG. 14A, the transfer control device 300 applies the voltage to the first and second stamps 310-1 and 310-2 to operate the first and second stamps 310-1 and 310-2.

Subsequently, as the first and second elastic portions 320-1 and 320-2 move vertically downward, the plurality of first and second element transfer portions 330-1 and 330-2 respectively provided on the first and second stamps 310-1 and 310-2 are in contact with the plurality of light-emitting elements ED-1 and ED-2 provided on the wafer substrate 210. In this case, each of the first and second elastic portions 320-1 and 320-2 may be composed of a spring or other materials having an elastic restoring force.

Next, the first and second adhesive portions 340-1 and 340-2 respectively provided on the first and second element transfer portions 330-1 and 330-2 pick up the plurality of light-emitting elements ED-1 and ED-2 respectively and separate the light-emitting elements ED-1 and ED-2 from the wafer substrate 210. In this case, when the voltage is applied to the first and second stamps 310-1 and 310-2 by the transfer control device 300, heat is applied to the first and second adhesive portions 340-1 and 340-2 to increase an adhesive property. Accordingly, the first and second adhesive portions 340-1 and 340-2 may be in contact with and may adhere to the plurality of light-emitting elements ED-1 provided on the wafer substrate 210. The plurality of light-emitting elements ED-1 adhering in a contact state may be picked up while adhering to the first and second adhesive portions 340-1 and 340-2 and may be separated from the wafer substrate 210.

Referring to FIG. 14B, in a state in which the transfer control device 300 is moved to the second transfer region T2 of the substrate 110, the plurality of light-emitting elements ED-1 and ED-2 picked up on the substrate 110 located in the second transfer region T2 are transferred.

In this case, the second transfer region T2 includes the display region AA and the non-display region NA. Specifically, the non-display region NA may include the trimming line TRL and the round region RA.

For example, when the voltage is not applied to the first stamp 310-1, the light-emitting element ED-1 may be transferred onto the substrate 110, and when the voltage is applied to the second stamp 310-2, the light-emitting element ED-2 may be not transferred onto the substrate 110.

The transfer control device 300 reads the data of the transfer coordinates A1-1, A1-2, A1-3, and A1-4 located in the display region AA of the second transfer region T2, and does not apply the voltage to the first stamp 310-1 located in the display region AA of the second transfer region T2.

Alternatively, the transfer control device 300 reads the data of the non-transfer coordinates N1-1, N1-2, N1-3, and N1-4 located in the non-display region NA of the second transfer region T2, and maintains the state in which the voltage is continuously applied to the second stamp 310-2 located in the non-display region NA of the second transfer region T2.

In this case, as static electricity is turned off from the plurality of first element transfer portions 330-1 provided on the first stamp 310-1 to which the voltage is not applied, and the light-emitting element ED-1 which was in contact with the first adhesive portion 340-1 is separated from the first adhesive portion 340-1, the light-emitting element ED-1 is transferred onto the substrate 110.

Alternatively, since the static electricity is continuously maintained from the plurality of second element transfer portions 330-2 provided on the second stamp 310-2 to which the voltage is applied, the light-emitting element ED-2 which was in contact with the second adhesive portion 340-2 continues to maintain contact with the first adhesive portion 340-1. For example, the light-emitting element ED-2 is not transferred onto the substrate 110.

Thus, the light-emitting element ED-1 may be selectively transferred to the region where transfer is required through the stamp control of the transfer control device 300.

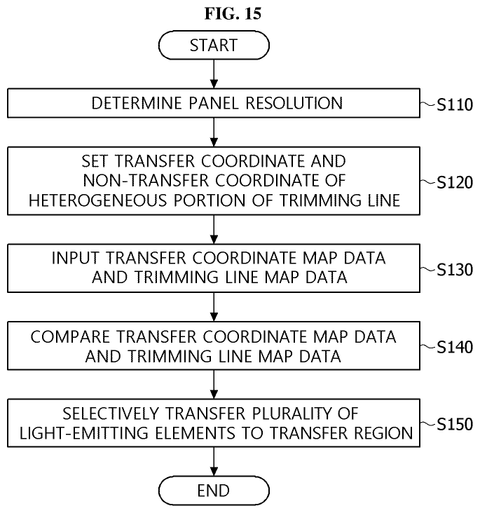

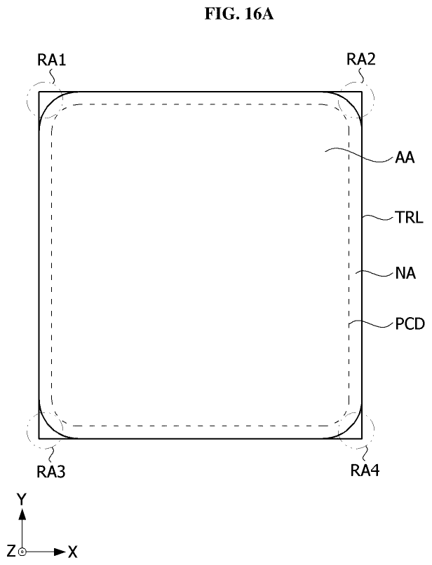

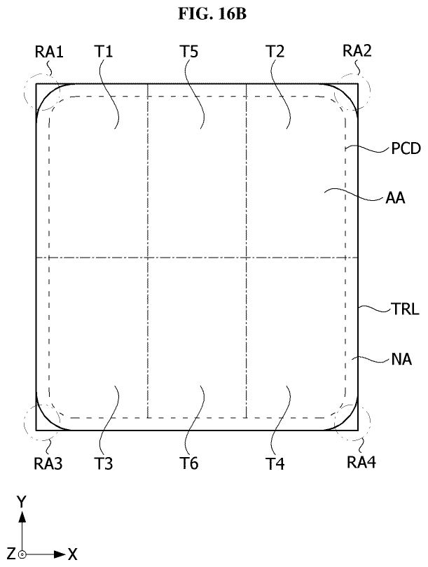

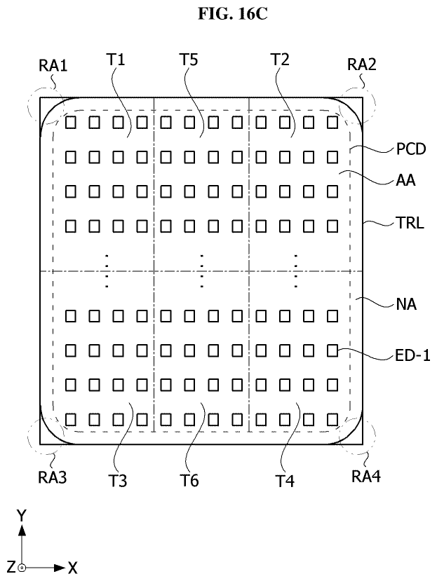

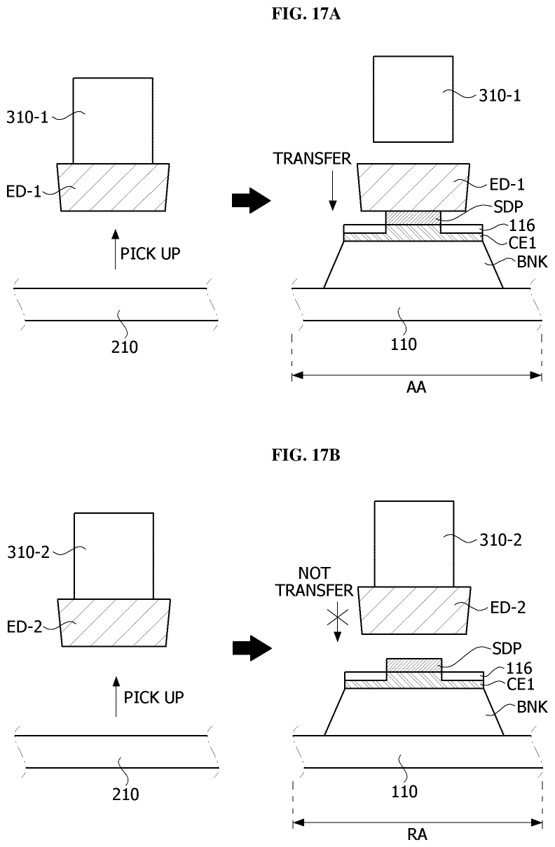

FIG. 15 is a flowchart of a transfer process of the light-emitting element in the display device according to an exemplary embodiment of the present disclosure. FIGS. 16A to 16C are process diagrams for transferring the light-emitting element of the display device according to an exemplary embodiment of the present disclosure. FIG. 17A is an enlarged cross-sectional view showing a transfer process of the light-emitting element in the display region in the display device according to an exemplary embodiment of the present disclosure. FIG. 17B is an enlarged cross-sectional view showing a non-transfer process of the light-emitting element in the non-display region in the display device according to an exemplary embodiment of the present disclosure.

Referring to FIG. 15, as a first operation S110, a desired panel resolution on the substrate 110 may be determined. For example, the number of light-emitting elements disposed in the panel is determined according to the degree of the panel resolution.

Subsequently, as a second operation S120, the transfer coordinates in the display region of the substrate and the non-transfer coordinates in a heterogeneous portion outside the curved boundary line in the non-display region may be set.

For example, referring to FIG. 16A, the map data of transferable positions where the light-emitting elements of the display region AA are transferred on the substrate 110 and the non-transfer position coordinates in the heterogeneous portion RA of the trimming line TRL included in the non-display region NA may be set. In this case, the non-display region NA surrounds the display region AA and may include the trimming line TRL, the PCD line PCD, and a trimming margin TM region therebetween. Further, the non-display region NA may include the heterogeneous portion RA including the inside and outside of the curved boundary line of the trimming line TRL. Here, the trimming margin TM may be defined at a certain interval inside and outside the trimming line TRL to have a trimming process margin while laser trimming using the trimming line TRL. Further, the non-display region NA may include first to fourth heterogeneous portions RA1, RA2, RA3, and RA4 inside and outside the curved boundary line of the trimming line TRL. The trimming line may also be interpreted as the bezel of the display panel which is a final product.

For example, the first to fourth transfer coordinates A1-1, A1-2, A1-3, and A1-4 which are present in the display region AA in the second transfer region T2 in FIG. 13 and the first to fourth non-transfer coordinates N1-1, N1-2, N1-3, and N1-4 in the heterogeneous portion RA of the trimming line TRL of the non-display region NA may be measured.

Next, as a third operation S130, the transfer coordinate map data and non-transfer coordinate map data may be input to the memory unit.

For example, referring to FIG. 16B, the transferable position map data of the display region AA in the first to sixth transfer regions T1 to T6, and the trimming line map data of the inside and outside of the curved boundary line of the trimming line TRL of the heterogeneous portion RA located in the non-display region NA may be transmitted and stored in the memory unit (not shown) in the transfer control device (300 in FIG. 14A).

Subsequently, as a fourth operation S140, the transferable position map data of the display region AA and the trimming line map data of the heterogeneous portion RA of the non-display region NA are compared and analyzed.

Next, after comparing and analyzing the transferable position map data and the trimming line map data of the heterogeneous portion RA, the transfer coordinates of the display region AA and the non-transfer coordinates of the heterogeneous portion RA including the curved boundary line of the trimming line TRL of the non-display region (NA) may be determined.

Subsequently, as a fifth operation S150, the plurality of light-emitting elements are selectively transferred to the transfer region. As one example, the voltage may be applied to the stamp on the non-transfer coordinates in the non-display region and the voltage may be not applied to the stamp located on the transfer coordinates in the display region, and thus the plurality of light-emitting elements may be only transferred to the transfer coordinates in the display region, and the plurality of light-emitting elements may be not transferred to the transfer coordinates in the non-display region.

For example, referring to FIG. 16C, the plurality of light-emitting elements ED-1 located in the display region AA may be transferred onto the substrate 110 in a state in which the plurality of picked-up light-emitting elements ED-1 and ED-2 are moved to an upper side of the substrate 110. In this case, through the voltage control of the transfer control device 300, as the voltage is not applied to the first stamp 310-1 to which the plurality of light-emitting elements ED-1 located in the display region AA, for example, the transfer region adhere, and thus static electricity is turned off from the first element transfer portion 330-1, the plurality of light-emitting elements ED-1 may be separated from the first adhesive portion 340-1 and transferred onto the plurality of banks BNK-1 on the substrate 110.

Specifically, referring to FIG. 17A, a solder pattern SDP may be disposed on a first electrode CE1. The solder pattern SDP may bond the light-emitting elements ED-1 to the first electrode CE1. The first electrode CE1 and the light-emitting elements ED may be electrically connected by eutectic bonding using the solder pattern SDP, but the embodiments of the present disclosure are not limited thereto.

Further, a second insulating layer 116 may be disposed on a fourth organic insulating layer including the first electrode CE1 and the bank BNK. For example, the second insulating layer 116 may be entirely disposed in the display region AA and the non-display region NA. However, the present disclosure is not limited thereto. For example, since the second insulating layer 116 may be disposed to cover the remaining regions excluding the bending region BA and the region where a plurality of pad electrodes PE and the solder pattern SDP are disposed, the penetration of moisture or impurities into the light-emitting element ED-1 through the second insulating layer 116 of an inorganic film material may be reduced.

Referring to FIG. 17B, as the voltage is applied to the second stamp 310-2 to which the plurality of light-emitting elements ED-2 located in the non-display region NA, for example, the non-transfer region, and thus the static electricity is maintained from the second element transfer portion 330-2, the plurality of light-emitting elements ED-2 are not separated from the second adhesive portion 340-2 but fixed, and thus are not transferred onto the plurality of banks BNK-1 on the substrate 110.

Accordingly, in the display device according to the present disclosure, as the voltage applied to the first and second stamps located on the transfer coordinates of the transfer region and the non-transfer coordinates of the non-transfer region is selectively controlled by the transfer control device 300 to individually drive the first and second stamps, the light-emitting elements may be effectively transferred only to the region where transfer is required.

Further, in the display device according to the present disclosure, as the heterogeneous transfer may be implemented by controlling the voltage applied to the stamp for transferring light-emitting elements through the transfer control device when the light-emitting elements are transferred, since the light-emitting element chips including inorganic films on an outer part of the panel are not transferred, moisture penetration may be prevented and reliability may be improved due to the removal of the light-emitting element chips in the trimming line.

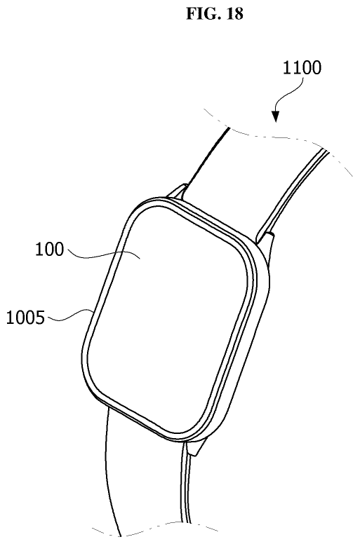

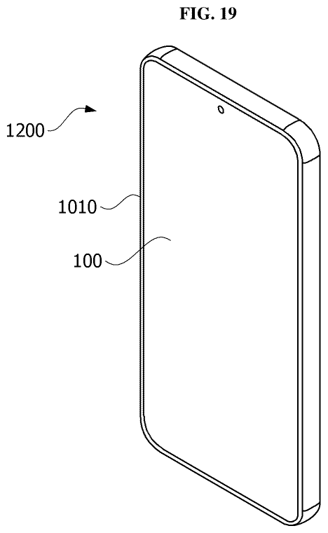

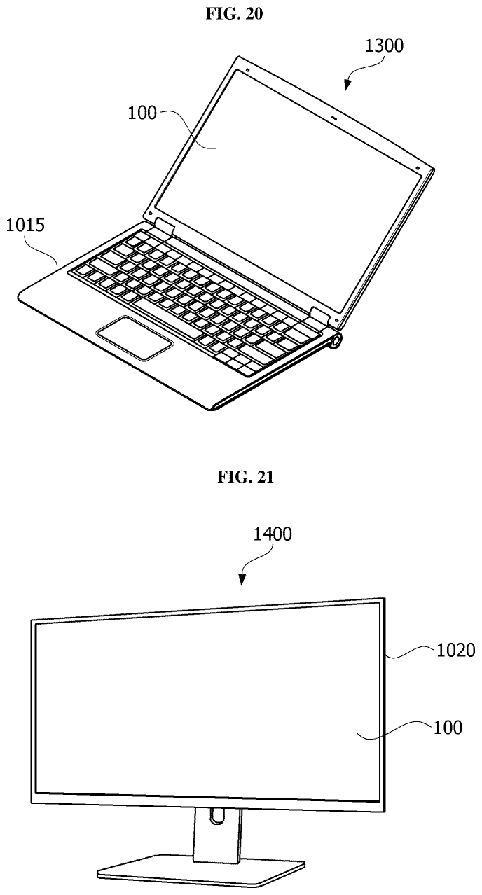

FIGS. 18 to 21 are views showing devices to which the display devices according to the embodiments of the present disclosure are applied.

Referring to FIGS. 18 to 21, the display devices 1000 according to the embodiments of the present disclosure may be included in various devices or electronic devices. For example, referring to FIGS. 18 to 21, various electronic devices may include a wearable device 1100, a mobile device 1200, a notebook 1300, and a monitor or television (TV) 1400, but the embodiments of the present disclosure are not limited thereto.

The wearable device 1100, the mobile device 1200, the notebook 1300, and the monitor or TV 1400 may respectively include case portions 1005, 1010, 1015, and 1020, and the above-described display panels 100 and display devices 1000 according to the embodiments of the present disclosure described in FIGS. 1 to 17B.

The display panel according to the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present disclosure may be applied to an organic light emitting lighting device or an inorganic light emitting lighting device. According to the present disclosure, interference between light-emitting element chips can be prevented, and a gap between layers, moisture penetration and corrosion after a reliability test, and the like can be improved by controlling transfer of light-emitting elements within a trimming line through heterogeneous transfer on an outer part of a display panel.

According to the present disclosure, as a voltage applied to first and second stamps located on the transfer coordinates of a transfer region and the non-transfer coordinates of a non-transfer region is selectively controlled by a transfer control device to individually drive the first and second stamps, light-emitting elements can be effectively transferred only to a region where transfer is required.

The effects according to the present disclosure are not limited to the above-mentioned effects, and other effects which are not mentioned can be clearly understood by those skilled in the art from the disclosure to be described below.

The display panel and the method of manufacture the same according to various embodiments of the present disclosure may be described as follows.

In one embodiment, a display panel comprises: a display region and a non-display region disposed outside the display region such that a curved boundary line is between the display region and the non-display region; and a plurality of light-emitting elements in the display region, wherein the plurality of light-emitting elements are disposed in the display region inside the curved boundary line and the non-display region outside the curved boundary line lacks any light-emitting elements.

In one embodiment, the display panel further comprises: a substrate including the display region and the non-display region; a pixel driving circuit on the substrate, the pixel driving circuit connected to the plurality of light-emitting elements; and an optical layer on side surfaces of the plurality of light-emitting elements.

In one embodiment, the display panel further comprises: a plurality of banks that support the plurality of light-emitting elements; a plurality of first electrodes between the plurality of banks and the plurality of light-emitting elements; and a plurality of signal lines that electrically connect the plurality of first electrodes and the pixel driving circuit.

In one embodiment, the display panel further comprises a plurality of contact electrodes electrically connected to the pixel-driving circuit and one or more second electrodes located on the optical layer and electrically connected to the plurality of contact electrodes.

In one embodiment, the display panel further comprises a buffer layer positioned between the substrate and the pixel-driving circuit, a first insulating layer disposed on the pixel-driving circuit, a protective layer disposed on the first insulating layer, and a second insulating layer disposed on the plurality of banks and on the protective layer.

In one embodiment, each of the buffer layer, the first insulating layer, and the second insulating layer includes an inorganic film.

In one embodiment, the buffer layer, the first insulating layer, and the second insulating layer are present in the display region but are absent from the non-display region.

In one embodiment, the non-display region outside the curved boundary line includes a heterogeneous portion that lacks any light-emitting elements.

In one embodiment, the display panel further comprises an optical layer on side surfaces of the plurality of light-emitting elements, one or more second electrodes on the optical layer, and a third insulating layer on the one or more second electrodes, the third insulating layer being present in the display region and absent from the non-display region.

In one embodiment, a display panel comprises: a heterogeneous portion including a display region and a non-display region with a curved boundary line as a boundary between the display region and the non-display region; and a plurality of light-emitting elements in the display region inside of the curved boundary line without any light-emitting elements in the non-display region outside of the curved boundary line.

In one embodiment, the display panel further comprises a substrate including the display region and the non-display region, a pixel-driving circuit on the substrate and connected to the plurality of light-emitting elements, and an optical layer on side surfaces of the plurality of light-emitting elements.

In one embodiment, the display panel further comprises a buffer layer between the substrate and the pixel-driving circuit, a first insulating layer on the pixel-driving circuit, a protective layer on the first insulating layer, and a second insulating layer on banks and on the protective layer.

In one embodiment, each of the buffer layer, the first insulating layer, and the second insulating layer includes an inorganic film.

In one embodiment, the buffer layer, the first insulating layer, and the second insulating layer are disposed in the display region but not in the non-display region.

In one embodiment, the non-display region comprises a first non-display area, a bending area, and a second non-display area, and the buffer layer and the second insulating layer are disposed in the display region, the first non-display area, and the second non-display area but are not disposed in the bending area.

In one embodiment, a method of manufacturing a display panel, comprises: providing a substrate including a display region and a non-display region where a curved boundary line is between the display region and the non-display region; and disposing a plurality of light-emitting elements in the display region inside the curved boundary line without disposing any light-emitting elements in the non-display region that is outside the curved boundary line.

In one embodiment, disposing the plurality of light-emitting elements comprises determining transfer-coordinate map data and non-transfer-coordinate map data, comparing the two sets of data, setting transfer coordinates that designate positions in the display region for placement of the plurality of light-emitting elements and setting non-transfer coordinates that designate positions in a heterogeneous portion outside the curved boundary line in the non-display region where light-emitting elements will not be placed, disposing stamps that pick up the plurality of light-emitting elements on the transfer coordinates and the non-transfer coordinates, applying a voltage to stamps located at the non-transfer coordinates while not applying a voltage to stamps located at the transfer coordinates, and transferring the plurality of light-emitting elements to the transfer coordinates in the display region using the stamps to which the voltage is not applied.

In one embodiment, the method further comprises disposing a pixel-driving circuit on the substrate, disposing an insulating layer on the substrate, and disposing an optical layer on side surfaces of the plurality of light-emitting elements.

In one embodiment, the method further comprises disposing a plurality of banks that support the plurality of light-emitting elements, disposing a plurality of first electrodes between the plurality of banks and the plurality of light-emitting elements, disposing a plurality of signal lines that electrically connect the plurality of first electrodes with the pixel-driving circuit, disposing a plurality of contact electrodes electrically connected to the pixel-driving circuit, and disposing one or more second electrodes on the optical layer and electrically connected to the plurality of contact electrodes.

In one embodiment, the method further comprises disposing a buffer layer between the substrate and the pixel-driving circuit, disposing a first insulating layer on the substrate including the banks, and disposing a second insulating layer on the one or more second electrodes.

Although embodiments of the present disclosure have been described in more detail with reference to the accompanying drawings, the present disclosure is not necessarily limited to the embodiments, and various modifications may be carried out without departing from the technical spirit of the present disclosure.

Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display panel comprising:
a display region and a non-display region disposed outside the display region such that a curved boundary line is between the display region and the non-display region; and
a plurality of light-emitting elements in the display region,
wherein the plurality of light-emitting elements are disposed in the display region inside the curved boundary line and the non-display region outside the curved boundary line lacks any light-emitting elements.

2. The display panel of claim 1, further comprising:
a substrate including the display region and the non-display region;
a pixel driving circuit on the substrate, the pixel driving circuit connected to the plurality of light-emitting elements; and
an optical layer on side surfaces of the plurality of light-emitting elements.

3. The display panel of claim 2, further comprising:
a plurality of banks that support the plurality of light-emitting elements;
a plurality of first electrodes between the plurality of banks and the plurality of light-emitting elements; and
a plurality of signal lines that electrically connect the plurality of first electrodes and the pixel driving circuit.

4. The display panel of claim 3, further comprising:
a plurality of contact electrodes electrically connected to the pixel driving circuit; and
one or more second electrodes on the optical layer, the one or more second electrodes electrically connected to the plurality of contact electrodes.

5. The display panel of claim 4, further comprising:
a buffer layer between the substrate and the pixel driving circuit;
a first insulating layer on the pixel driving circuit;
a protective layer on the first insulating layer; and
a second insulating layer on the plurality of banks and the protective layer.

6. The display panel of claim 5, wherein each of the buffer layer, the first insulating layer, and the second insulating layer includes an inorganic film.

7. The display panel of claim 6, wherein the buffer layer, the first insulating layer, and the second insulating layer are disposed in the display region but not disposed in the non-display region.

8. The display panel of claim 1, wherein the non-display region outside the curved boundary line includes a heterogeneous portion that lacks any light-emitting elements.

9. The display panel of claim 1, further comprising:
an optical layer on side surfaces of the plurality of light-emitting elements;
one or more second electrodes on the optical layer; and
a third insulating layer on the one or more second electrodes,
wherein the third insulating layer is disposed in the display region and is not disposed in the non-display region.

10. A display panel comprising:
a heterogeneous portion including a display region and a non-display region with a curved boundary line as a boundary between the display region and the non-display region; and
a plurality of light-emitting elements in the display region inside of the curved boundary line without any light-emitting elements in the non-display region outside of the curved boundary line.

11. The display panel of claim 10, comprising:
a substrate including the display region and the non-display region;
a pixel driving circuit on the substrate, the pixel driving circuit connected to the plurality of light-emitting elements; and
an optical layer on side surfaces of the plurality of light-emitting elements.

12. The display panel of claim 11, further comprising:
a buffer layer between the substrate and the pixel driving circuit;
a first insulating layer on the pixel driving circuit;
a protective layer on the first insulating layer; and
a second insulating layer on banks and the protective layer.

13. The display panel of claim 12, wherein each of the buffer layer, the first insulating layer, and the second insulating layer includes an inorganic film.

14. The display panel of claim 13, wherein the buffer layer, the first insulating layer, and the second insulating layer are disposed in the display region but not disposed in the non-display region.

15. The display panel of claim 12, wherein the non-display region comprises a first non-display area, a bending area, and a second non-display area, and the buffer layer and the second insulating layer are disposed in the display region, the first non-display area, and the second non-display area, but are not disposed in the bending area.

16. A method of manufacturing a display panel, comprising:
providing a substrate including a display region and a non-display region where a curved boundary line is between the display region and the non-display region; and
disposing a plurality of light-emitting elements in the display region inside the curved boundary line without disposing any light-emitting elements in the non-display region that is outside the curved boundary line.

17. The method of claim 16, wherein disposing the plurality of light-emitting elements comprising:
determining transfer coordinate map data and non-transfer coordinate map data;
comparing the transfer coordinate map data and the non-transfer coordinate map data;
setting transfer coordinates that specify locations in the display region of the substrate where the plurality of light-emitting elements will be disposed in the display region and setting non-transfer coordinates that specify locations in a heterogeneous portion outside the curved boundary line in the non-display region that light emitting-elements will not be disposed based on the comparison;
disposing stamps that pick up the plurality of light-emitting elements on the transfer coordinates in the display region and the non-transfer coordinates in the non-display region; and
applying a voltage to one or more of the stamps that are located at the non-transfer coordinates in the non-display region and not applying a voltage to one or more of the stamps that are located at the transfer coordinates in the display region, and transferring the plurality of light-emitting elements to the transfer coordinates in the display region using the one or more of the stamps that are not applied with the voltage.

18. The method of claim 16, further comprising:
disposing a pixel driving circuit on the substrate;
disposing an insulating layer on the substrate; and
disposing an optical layer on side surfaces of the plurality of light-emitting elements.

19. The method of claim 18, further comprising:
disposing a plurality of banks that support the plurality of light-emitting elements;
disposing a plurality of first electrodes between the plurality of banks and the plurality of light-emitting elements;
disposing a plurality of signal lines that electrically connect the plurality of first electrodes and the pixel driving circuit;
disposing a plurality of contact electrodes, the plurality of contact electrodes electrically connected to the pixel driving circuit; and
disposing one or more second electrodes, the one or more second electrodes electrically connected to the plurality of contact electrodes on the optical layer.

20. The method of claim 19, further comprising:
disposing a buffer layer between the substrate and the pixel driving circuit;
disposing a first insulating layer on the substrate including the bank; and
disposing a second insulating layer on the one or more second electrodes.
